(19) United States
(12) Patent Application Publication
(10) Pub. No.: US 2013/0146123 A1
(43) Pub. Date: Jun. 13, 2013

(54) Solar Panel Tracking and Mounting System

(71) Applicant: Ken Hyun Park, San Jose, CA (US)

(72) Inventor: Ken Hyun Park, San Jose, CA (US)

(21) Appl. No.: 13/762,687

(22) Filed: Feb. 8, 2013

Related U.S. Application Data
(63) Continuation of application No. 12/793,510, filed on Jun. 3, 2010.
(60) Provisional application No. 61/217,794, filed on Jun. 3, 2009.
(60) Provisional application No. 61/268,237, filed on Jun. 9, 2009.
(60) Provisional application No. 61/311,745, filed on Mar. 8, 2010.

(51) Int. Cl. H01L 31/052

(52) U.S. Cl. CPC H01L 31/052
USPC 136/246

(57) ABSTRACT

A method for tracking solar panels includes the steps (a) beginning a tracking cycle substantially at sunrise with adjacent tilting panels all horizontal, (b) tilting the adjacent panels in unison in a first angular direction toward the rising sun at a tilt rate that just avoids shading of adjacent panels, (c) reversing direction of panel tilt at a point that the panels reach either a maximum tilt limited by mechanical design, or the panel surfaces are orthogonal to the rising sun, (d) tilting the adjacent panels in a second angular direction, following movement of the sun and keeping the surface of the panels at right angles to the sun's position, until a point is reached that shadowing is imminent from the angle of the setting sun, and (e) reversing direction of panel tilt again to the first angular direction, adjusting tilt as the sun sets to avoid shading until the panels are again horizontal.

### CROSS-REFERENCE TO RELATED APPLICATIONS

The present invention is a continuation application of Ser. No. 12/793,510, filed Jun. 3, 2010, which claims priority to a U.S. provisional patent application Ser. Nos. 61/217,794, filed on Jun. 3, 2009, 61/268,237, filed on Jun. 9, 2009, and 61/311, 745, filed on Mar. 8, 2010, disclosures of which are incorporated at least by reference.

### BACKGROUND OF THE INVENTION

1. Field of the Invention

The present invention is in the field of solar tracking systems and pertains particularly to methods and apparatus for tracking the sun using at least one tilt angle while minimizing any shadowing on adjacent solar collection panels.

2. Discussion of the State of the Art

In the field of solar tracking systems, there are system that can produce substantially more energy (watts/panel) compared to fixed arrays of the same type and capacity by enabling tracking of the sun. This difference is most pronounced for those using crystalline silicon PV technologies, where a single-axis tracking systems could add up to 30% more energy. However, there is a drawback involved. When one side of array is raised at low sun angles, the arrays cast larger shadows and require greater separation compared to their fixed counterparts. Again, this penalty is costliest for crystalline PV systems because relatively small shading may result in a disproportionate reduction in power generated by the system.

The overriding objective of a typical commercial or residential rooftop installation is to achieve the highest energy density within a confined rooftop space. Obviously, the extra spacing lowers installation density in terms of the number of panels/unit of area. Because of the space, weight and other constraints, the fast-growing commercial segment has been largely bypassing the conventional tracking option.

Today, practically all rooftop-based commercial solar installations are fixed and most of the tracking systems can be found in large utility-scale ground-based installations in remote areas where space is relatively inexpensive and abundantly available. Therefore, what is clearly needed is a solar tracking system and method for tracking the sun that can minimize shadowing thrown on adjacent panels and allow for more panels to be placed in a smaller footprint without reducing the amount of efficiency of the system.

### SUMMARY OF THE INVENTION

The problem stated above is that maximum efficiency is desirable for a solar collector system or array, but many of the conventional means for maximizing solar energy collection is solar system also create complexity and cost. The inventors therefore considered functional elements of a modular solar collector system, looking for elements that exhibit interoperability that could potentially be harnessed to provide energy but in a manner that would not create drag.

Every solar system is propelled by the suns rays, one by-product of which is an abundance of stored energy that can be utilized directly. Most such systems employ solar panels and tilting means to minimize angle of incidence (AOI) thereby increasing energy savings.

The present inventor realized in an inventive moment that if, during solar tracking, modular solar collecting devices could be caused to track the sun in unison using both synchronous and counter synchronous tracking such that by one or more pivot axis' the panels may be caused to tilt and/or track along those axis', more solar efficiency in solar energy collection might be realized. The inventor therefore constructed a unique modular system of solar collection devices for rooftops and commercial installations that allowed minimization of AOI during solar tracking thereby increasing solar collection efficiency during the solar tracking operation. A significant reduction in work results, with no impediment to solar footprint or existing solar efficiency ratings created.

Accordingly, in an embodiment of the present invention, a method for tracking solar panels is provided comprising the steps of (a) beginning a tracking cycle substantially at sunrise with adjacent tilting panels all horizontal, (b) tilting the adjacent panels in unison in a first angular direction toward the rising sun at a tilt rate that just avoids shading of adjacent panels, (c) reversing direction of panel tilt at a point that the panels reach either a maximum tilt limited by mechanical design, or the panel surfaces are orthogonal to the rising sun, (d) tilting the adjacent panels in a second angular direction, following movement of the sun and keeping the surface of the panels at right angles to the sun's position, until a point is reached that shadowing is imminent from the angle of the setting sun; and (e) reversing direction of panel tilt again to the first angular direction, adjusting tilt as the sun sets to avoid shading until the panels are again horizontal.

In one aspect of the method in steps (b) and (e), tilting allows a pre-programmed percentage of shading to occur. In a variation of this aspect, in steps (b) and (e) the tilting allows a pre-programmed constant percentage of shading to occur.

In a variation of this aspect, in steps (b) and (e) the tilting allows a pre-programmed percentage of shading to occur, and the percentage varies with angle of tilt. In one aspect the tilting is accomplished in a continuous motion. In another aspect the tilting is accomplished incrementally at pre-programmed time increments.

In one aspect of the present invention a solar panel system is provided and includes a plurality of solar panels having a length substantially greater than a width mounted side-by-side with each panel enabled to tilt about along an axis in the direction of the length of the panel, a tilting mechanism coupled to adjacent panels, capable of tilting the panels in either of two rotating directions about the panel axes, and a programmable drive control enabled to control the rate and direction of tilt for the panels in unison in a tracking cycle.

The tracking cycle begins substantially at sunrise with the panels horizontal, the panels are tilted in unison in a first angular direction toward the rising sun at a tilt rate that just avoids shading of adjacent panels, direction of tilt is reversed at a point that the panels reach either a maximum tilt limited by mechanical design, or the panel surfaces are orthogonal to the rising sun, the panels are tilted in a second angular direction, following movement of the sun and keeping the surface of the panels at right angles to the sun's position, until a point is reached that shadowing is imminent from the angle of the setting sun, and tilting direction is reversed again to the first angular direction, adjusting tilt as the sun sets to avoid shading until the panels are again horizontal.

In one embodiment the tilting allows a pre-programmed constant percentage of shading to occur. In another embodiment the tilting allows a pre-programmed percentage of shading to occur, and the percentage varies with angle of tilt. In one embodiment tilting is accomplished in a continuous motion. In another embodiment tilting is accomplished incrementally at pre-programmed time increments.

### BRIEF DESCRIPTION OF THE DRAWING FIGURES

FIG. 1 is a block diagram illustrating tilt capabilities of a solar collection device for maximizing exposure to the sun.

FIG. 2 is a perspective view of a modular solar device including brackets for installation.

FIG. 3 is a perspective view of a modular solar device having slot adapters for installation.

FIG. 4 is a side view of a modular solar device illustrating horizontal tilt capability according to an embodiment of the present invention.

FIG. 5 is a perspective view of a standard solar panel installation.

FIG. 6 is a perspective view of a modular device according to an embodiment of the present invention.

FIG. 7 is a perspective view of a modular solar array according to an embodiment of the present invention.

FIG. 8 is an architectural overview of an integrated network for remote access and maintenance of a system of flat-panel arrays.

FIG. 9 is a perspective view of a modular device array according to an embodiment of the present invention.

FIG. 10 is a perspective view of a modular device array including a lateral transfer system according to another embodiment of the present invention.

FIG. 11 is a perspective view of a flat panel array according to another embodiment of the present invention.

FIG. 12 is a perspective view of several gantry robot configurations according to an embodiment of the present invention.

FIG. 13 is a cutaway view of a multi track robot according to an embodiment of the present invention.

FIG. 14 is a cutaway view of a multi-track robot according to another embodiment of the present invention.

FIG. 15 is a perspective view of optional hose or cable feeder/tensioner assemblies for use in cleaning operations according to embodiments of the present invention.

FIG. 16 is a top view of a robot tracking on a hybrid tracking system 1600 according to an embodiment of the present invention.

FIG. 17 is a top view of a robot tracking on a hybrid tracking system according to another embodiment of the present invention.

FIG. 18 is a top view of a robot tracking on a tracking system according to a further embodiment of the present invention.

FIG. 19 is a logical block diagram illustrating angle of incidence (AOI) of the sun against a solar array.

FIG. 20 is a block diagram illustrating an angular range of motion (AROM) for a solar panel according to an embodiment of the present invention.

FIG. 21 is an elevation view of a modular device illustrating inter-array spacing or separation.

FIG. 22 is a chart illustrating retrograde tracking according to an embodiment of the present invention.

FIG. 23 through FIG. 27 are block diagrams illustrating two solar units in various states of solar tracking in unison.

FIG. 28 is a perspective view illustrating two array configuration options according to an embodiment of the present invention.

FIG. 29 is a perspective view of a single sub-frame section of linkable frame component of FIG. 28.

FIG. 30 is a partial view of a frame member according to an embodiment of the present invention.

FIG. 31 is a perspective view of frame member of FIG. 30 showing outer skin and multiple tilt mechanisms.

FIG. 32 is a block diagram illustrating basic tracking module components of a tracking module.

FIG. 33 is a partial view of a frame member of the modular solar collecting system of the present invention.

### DETAILED DESCRIPTION

The inventor provides a modular solar collector system that has dual sun-tracking capabilities, self-inspection and self-cleaning maintenance capabilities, and other general improvements over standard art systems for residential and commercial use. The present invention is described in enabling detail using the following examples, of which may show more than one useful embodiment of the present invention.

The terms solar panel and solar module are commonly used interchangeably in documents that describe conventional solar collecting systems. However, in this specification, and to avoid confusion, the terms modular solar collecting device or simply modular device shall be used to reference a fully-functioning solar collecting unit enclosed in a rigid sub-structure with full electrical and/or thermal connections. The modular device of the present invention two or more such devices comprising a modular solar collecting system, may be functionally similar to solar panels/modules in the conventional system with respect to solar collecting technologies and may encompass, but may not be limited to, mono or poly-crystalline silicon photovoltaic (PV), thin-film-based PV, concentrator PV (CPV) and concentrating solar thermal (CST) technologies.

Modular Solar Collecting System with Linking Hardware and Device Tilting Capability

Modular devices of the present invention may or may not be longer in length than conventional solar panels, but are likely to be narrower in width compared to their conventional counterparts. Wider devices have larger axial tilting radii requiring greater mounting heights for ground clearance, which is a problem in the art that the present invention is designed to overcome. For the purposes of this specification, an integrated group of modular devices comprises a modular subsystem and one or more of installed modular subsystems comprise a modular sub-system array. A typical solar installation, whether commercial or residential, has one or more arrays.

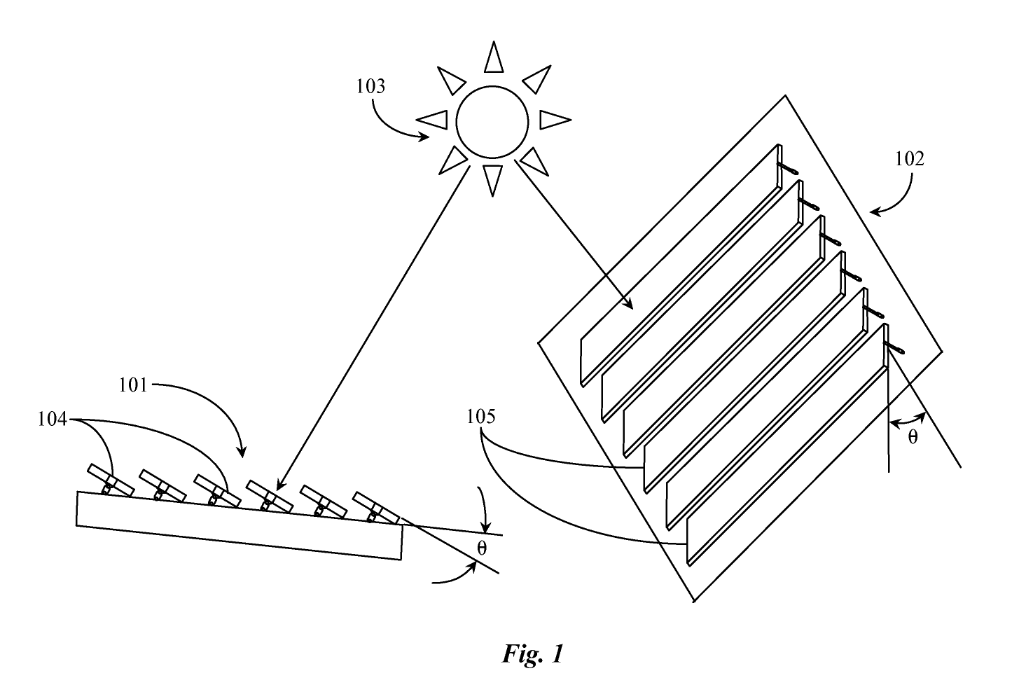

FIG. 1 is a block diagram illustrating tilt capabilities of a solar collection device for maximizing exposure to the sun. To attain the maximum efficiency in collecting solar rays, the surfaces of solar collecting devices should be orthogonal to the sun at noon when its intensity peaks. In reality however, the orientations of installation surfaces of solar systems are rarely optimal. Tilting compensates for poor device orientation (steep/shallow sloping surface or offset from true south in the northern hemisphere). Therefore a capability of tilting the devices can work to correct offset angles (θ).

A solar collecting device 101 has panels 104 that tilt horizontally to optimize the exposure to sun 103. A solar collecting device 102 has solar panels 105 that compensate or adjust for meridian of sun 103. Therefore a modular solar device has panels that may tilt horizontally and vertically to optimize exposure to the sun thus maximizing the efficiency of the unit.

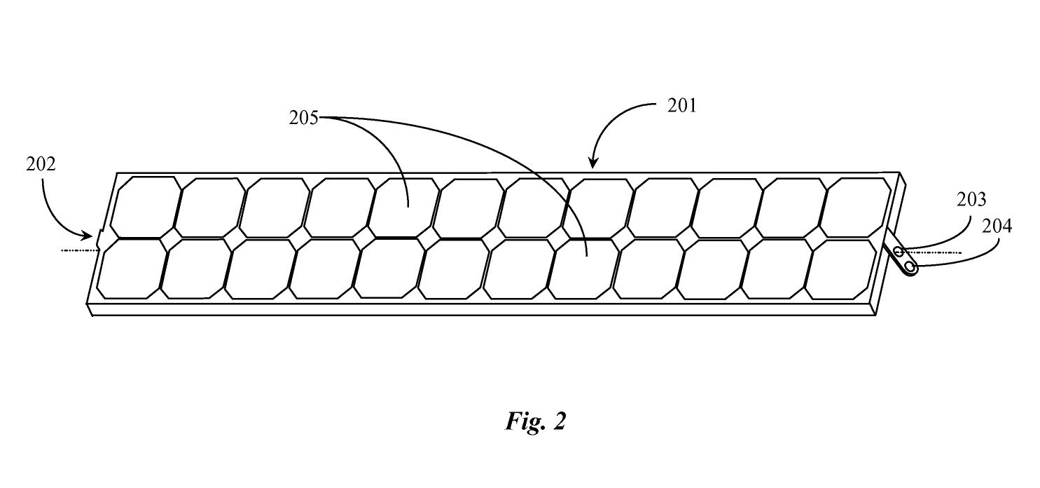

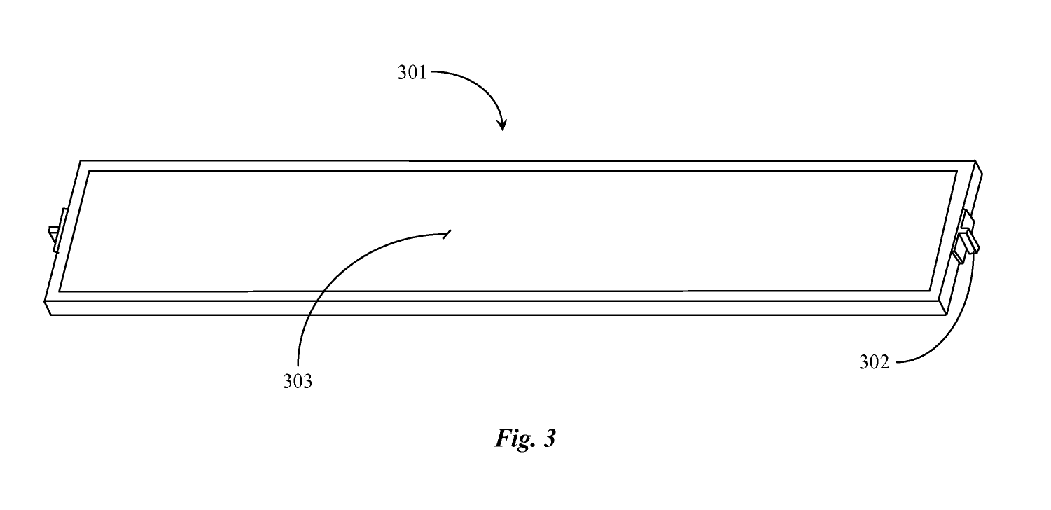

FIG. 2 is a perspective view of a modular solar device including brackets for installation. FIG. 3 is a perspective view of a modular solar device having slot adapters for installation. Referring now to FIG. 2, a modular device 201 may be manufactured of 2×12 silicon-based PV cells 205. Device 201 includes mounting brackets (202), one per side. Mounting brackets 202 include upper and lower pivot points 203 and 204 respectively. A dashed line is illustrated in this example and represents the tilt axis of the device.

Referring now to FIG. 3, a modular solar collecting device 301 is illustrated and includes a uniform coating 303 of thin-film PV. Device 301 includes slot adapters 302, one at each end in this example. Slot adapters 302 may be of various shapes and sizes. The slot adapters are mated to slot receptacles, (not illustrated) on a frame component to establish mechanical connection. Carbon composites or other light weight materials may be used in manufacture of the modular device's sub-structure. Individual modular devices may or may not be equipped with dedicated micro-inverters (not illustrated) that convert DC modular devices into AC modular devices.

In one embodiment a modular device with tilting capability comprises a section of extruded rectangular tubing having a top surface, a bottom surface and two side surfaces. Photovoltaic or other types of solar cells, PV coatings or a combination may be applied to the top surface, the bottom surface, and the side surfaces in order to improve overall efficiency by harvesting power from indirect light either reflected or refracted to the bottom and side surfaces of the device. In one aspect of this configuration thin film PV coatings may be used on the sides and bottom surface of the modular device. As costs continue to come down for thin film coatings, the practicality of employing them to enhance efficiency by applying them on secondary device surfaces may become more practical.

In one embodiment a modular subsystem includes multiple modular solar collecting devices, a frame that holds the modular devices and hardware that connect individual modular devices together and provides pivot points. A frame (not illustrated here) may be as simple as a rectangular box with angled cutouts for “hanging” modular devices at a desired angle. In another embodiment a frame may include pivot points and a tilting mechanism incorporated within the thickness of its wall. In a “plug and play” embodiment, modular devices may be pushed into slotted and pivoted receptacles built into the sides of a frame. The simple insertion may lock the devices in place and establish both mechanical and electrical connections.

Frames provided to contain modular devices may be made of any one of a number of hard man-made/synthetic materials such as steel, aluminum, fiberglass, carbon composite, or plastics, depending in part on cost, weight and durability. Frames may or may not be manufactured using molding or extrusion method. Pre-drilled holes, notches and other provisions may facilitate easy fastening to various types of installation surfaces. Pre-fabricated frames may be available in different lengths to hold fixed numbers of modular devices, but two end plates may be identical. Made-to-order frames, however, may accommodate any number of modular devices as required by end-user.

In a conventional system solar collectors or cells, for example, are directly installed on a simple rack structure. In the modular system of the present invention, it is preferable to first mount a number of modular devices in a rigid rectangular frame that mechanically connects them together in a parallel “louver-like” arrangement. The mechanical connections allow them to tilt in sync as a single integrated unit. Electrical and thermal integration may be also made at this point. The framing and the interconnections transform these modular devices into a modular subsystem that is ready to be installed. The modular subsystem is comprised of modular solar collecting devices, a frame that holds the modular devices and hardware that connect individual modular devices together and provides pivot points.

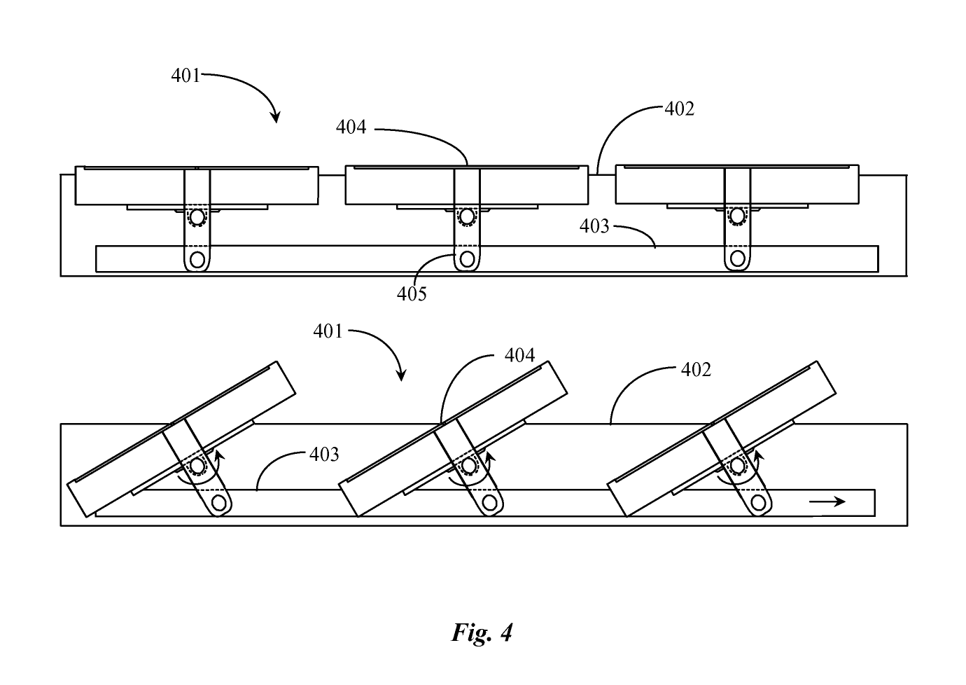

FIG. 4 is a side view of a modular solar device 401 illustrating horizontal tilt capability described further above according to an embodiment of the present invention. Modular solar device 401 contains multiple modular solar collecting devices 405, which may be analogous to solar devices 201 described further above in this specification.

In this example, devices are mounted on a frame 402 by the upper pivot points allowing the devices to tilt axially (lengthwise). The lower pivot points may be connected to a tilt bar or device connection bar 403. The device connection bar 403 enables a synchronized tilt of the installed devices to an angle that is appropriate for maximizing energy collection according to position of the sun.

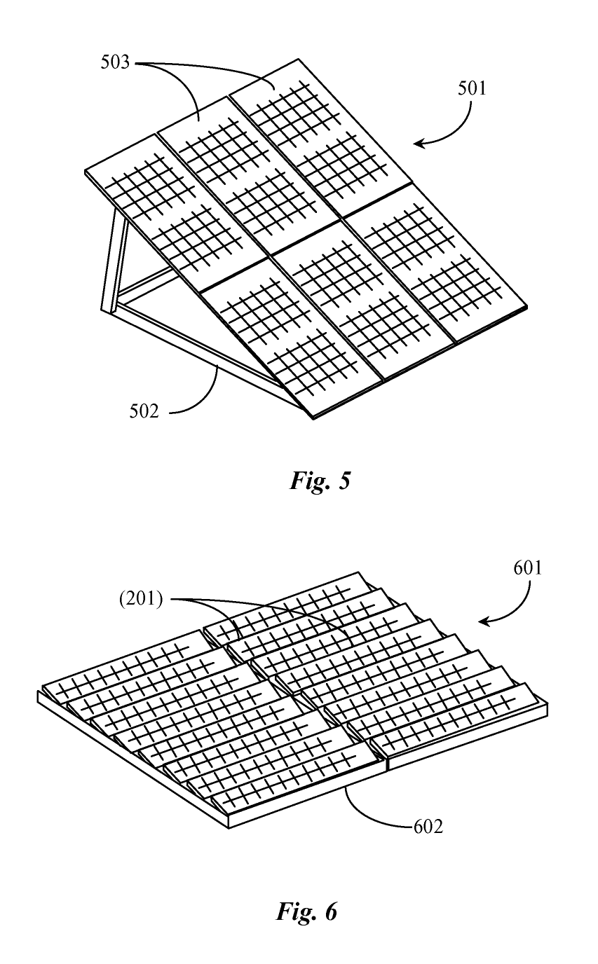

FIG. 5 is a perspective view of a standard solar panel installation. FIG. 6 is a perspective view of a modular device according to an embodiment of the present invention. Referring now to FIG. 5 and to FIG. 6, the two arrays illustrated underscore the difference between the conventional and modular systems. Referring now to FIG. 5, a conventional solar array 501 is illustrated. Solar array 501 comprises an aggregation of panels 503 onto a racking structure 502. Racking structure 502 is provided at a fixed elevation in order to orientate the array toward the sun. However, this tilting method is only practical for installations on flat surfaces. For sloped rooftop installations where solar arrays need to be “flush” with the roof, such elevation is usually not an option. As a result, a majority of conventional rooftop installations face less than ideal angles and therefore are less efficient in collecting energy.

Referring now to FIG. 6, a modular solar array 601 is provided and may be installed directly on the installation surface without any racking structure like racking structure 502. To install a modular array, blank frames such as a frame 602 may be first positioned, shimmed and fastened to the installation surface. Then modular devices such as devices 201 may be installed inside one-by-one until the frames are filled. Finally, the tilt adjustment may be made within the frames. This installation process may reduce labor cost. The low-profile mounting and tilting means superior installation flexibility.

So far in this specification tilting of solar collection devices has been illustrated as a way to optimize the angle of incidence in contact with the solar rays. While tilt adjustments may be sufficient for some solar installations, a much greater level of efficiency may be obtained through passive and or active tracking of the Sun. Tracking for the purposes of this specification shall mean the continuous following of the sun to maintain the optimal angle of the suns rays against a modular device as long as possible. The modular subsystem of the present invention includes a built-in synchronized tilting capability that make solar tracking easily attainable. For example, a tracking module (not illustrated) installed over one of the end plates of the system may convert any modular subsystem into a low-profile tracking system that is practical even for small rooftop installations.

In such a system, inside the tracking module, tracking motion may be attained in a number of ways including but not limited to using an in-line actuator or motor and screw set, or perhaps a transverse-mounted motor and hinged arm set. Such a tracking module may also house motion control electronics as well as a wired or wireless network adapter card allowing its status to be viewed by a remote computer. The maximum length of tracking modular subsystem should be limited only by the size/power of the actuator or motor used.

To install a solar array using the system described here, an installer may first select different combinations of frames (various types and sizes including custom sizes) that best suits system requirements or needs and then populates those frames with a like different combination of modular devices of his/her choosing. Later, a tracking module may be added to the system by plugging it into the system. Such plug and play installation allows the module to function seamlessly and harmoniously with the rest of the system qualifying the system as a true modular system.

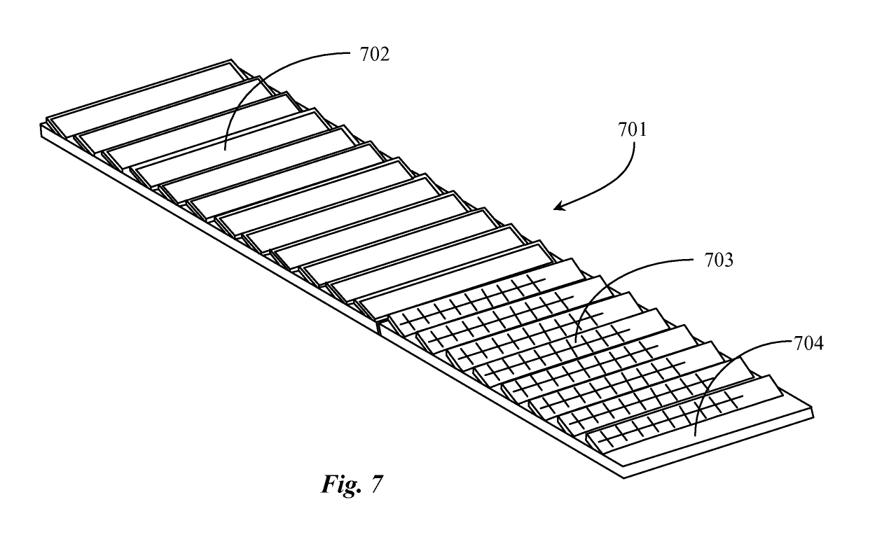

FIG. 7 is a perspective view of a modular solar array 701 according to an embodiment of the present invention. In one embodiment, modularity of the system may extend beyond the boundaries of subsystem frames. Array 701 has mechanical linkages (not illustrated) established between modular subsystems that allow all of the modular devices such as devices 702 and 703 in the array to tilt together in unison. Devices 702 are thin film-based while devices 703 are silicon-based. Other types may also be added into the installation without departing from the spirit and scope of the present invention.

In one embodiment the linkage may be serially connected (lengthwise as shown below). In another embodiment the linkage may be parallel (side to side). A combination of the two may also be implemented without departing from the spirit and scope of the present invention. A tracking module 704 is provided at one end of one modular subsystem. Tracking module 704 enables the entire array to track the sun. Although not specifically illustrated here, the physical connection among the modular subsystems may be accomplished in multitudes of ways. For example, in one embodiment is a metal extension strip that clips on between two adjacent device connection bars that control tilt angles through cutouts on end-plates. In another embodiment, electrical and other types of linkages between modular subsystems may be simultaneously established.

It will be apparent to a skilled artisan that the embodiments described above are exemplary of inventions that may have greater scope than any of the singular descriptions. There may be many alterations made in these examples without departing from the spirit and scope of the invention. For example, different modular subsystems may have modular solar collecting devices of different lengths and widths. One or more mounting brackets of many shapes, sizes and materials may be implemented at various positions. Tilting of modular arrays can be achieved in a variety of ways within a frame. Motors or actuators for tracking may be integrated with modular subsystems. A tracking drive may have an in-line actuator or AC/DC motor and may also use components such as gears, screws, levers, pulleys, belts, chains, or cords for power transmission without departing from the spirit and scope of the present invention.

### Self-Monitoring, Cleaning, and Maintenance

In addition to the useful embodiments describing a modular solar array above, the inventor further provides a system and methods for automated self-monitoring and cleaning and provision of other maintenance needs for a solar array or for another type of flat panel array such as glass or other hard and smooth surfaces not necessarily limiting to modular solar arrays. The present invention is described in enabling detail using the following examples, which may include descriptions of more than one embodiment of the invention. In this specification, a flat panel shall mean a large flat surface of various dimensions made of glass, metal, or any other hard and smooth substances. Examples of flat panels include, but are not limited to solar panels and glass panels. An array shall mean a cluster of flat panels laid side by side that is physically separated from other clusters. Installations such as solar farms and glass façades of buildings may have any number of arrays greater than or equal to one.

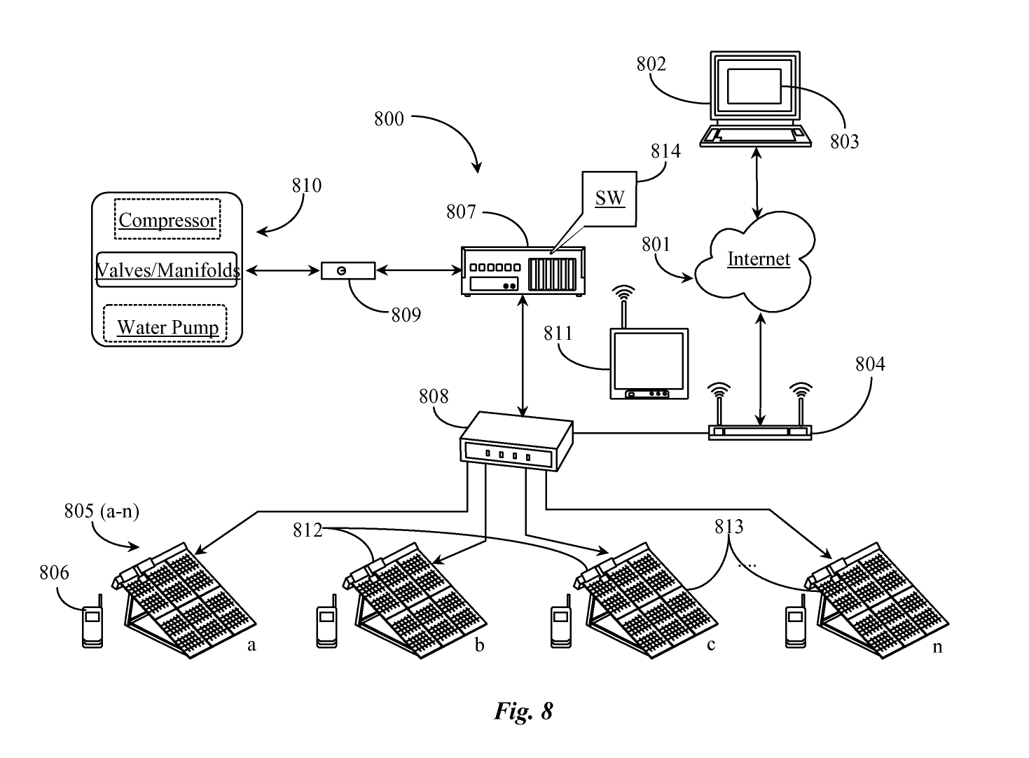

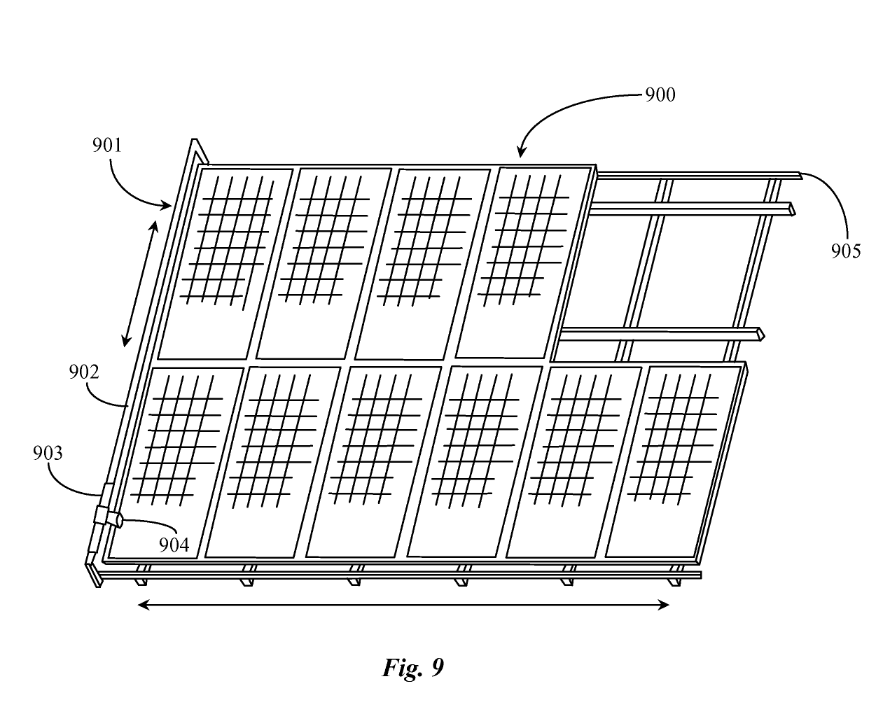

FIG. 8 is an architectural overview of an integrated network 800 for remote access and maintenance of a system of flat-panel arrays. Network 800 includes an installation of multiple photovoltaic flat-panel arrays 805 (a-n). Each array 805 (a-n) includes a robot 812 and a sensor unit 806. A robot 806 may be a cleaning robot equipped with delivery hoses for delivering a cleaning solution to the flat-panels, which are solar panels in this example. Modular solar devices may be substituted therefor in one embodiment of the invention. Robot 8121 may also include an optical component such as a camera eye for enabling a visual inspection of the surfaces of the flat panels in each array. Each device array 805 (a-n) is accessible through a switching facility 808.

The multiple device arrays share a single hardware component group 810 in this example. Hardware component group 810 includes a compressor, a number of valves and manifolds, and a water pump. It is noted that group 810 may include other shared components without departing from the spirit and scope of the present invention. The maintenance activity is controlled by a single intelligent controller 807. All communications to and from each array 805 (a-n) are routed through switching facility 808 as described above. Ethernet cables might be used form the single integrated network 800 to monitor, inspect, analyze, and maintain the entire installation in the optimal operating condition.

As described above, each array 805 represents a network node on network 800. Each array may have a network identification and network address. Each array 805 may include multiple solar panels 813, a dedicated robot 812, and a sensor unit 806. Sensor unit 806 may include a digital surface temperature probe for calibration and a current/voltage meter for performance metrics (sub-devices not illustrated). The measurements may be made for the array as a whole or on a panel-by-panel basis. The sensor unit may be replaced by certain smart micro-inverters that facilitate real-time data output.

Shared hardware 810 may include an air compressor, water pump and a system of digitally-controlled valves and manifolds that delivers air and liquid to robots 812 as directed by the controller via a hardware interface 809. Although not specifically required to practice the present invention, a firewall-equipped router and modem 804 may be provided and then connected to the Internet illustrated herein as Internet cloud 801 to enable an administrator to monitor and control the network remotely via a computer 802 or a smart phone. An optional wired/wireless wall-mounted display console or display monitor 811 may be used locally for similar purposes.

Although not required, controller 807 may serve as the brain for the entire distributed network. It may be equipped with an embedded single board computer, flash drive for data storage, and intelligent digital servo-drive for each axis of motion in the network. Controller 807 may be in constant communication with individual robots 812, sensors and shared hardware system 810, sending commands and receiving data. Smart network configuration software (SW) 814 may be provided on a suitable digital medium to be executed there from to auto-detect a new robot or axis and launch a SW configuration wizard. In this example the SW is implemented on the controller unit 807.

In one embodiment network 800 includes remote access capability through the Internet 801. In this case a GUI 803 may be accessed from a Website (not illustrated) using a remote computing appliance such as Laptop computer 802. GUI 803 may be provided so that a user may configure the maintenance of the system remotely through the Internet or some other digital network accessible to the World Wide Web (WWW). A suite of applications and widgets (not illustrated) may be available via Web-based GUI for functions such as real-time condition/power monitoring, surface inspection, trend analysis, and other types of user queries and/or inputs.

In one embodiment of the invention controller 807 may monitor real-time data from the sensor units 806 to gauge the health and performance of each panel in each array. The controller may also splice together strips of thermal images taken from the imaging module of robot 812 (more detail latter in this specification), assign a cleanliness index, and make interpretations of any anomalies or potential issues relative to each inspected panel. Problems may be identified and possible remedies suggested by the controller with the aid of the ability to cross-reference and analyze two sets of real-time data with previously stored calibration and mined historical data.

The outcome of the analysis as suggested immediately above may result in an immediate initiation of an automated response such as “blow away the leaves on Panel #7” or “wash the entire array”). In one embodiment a report is generated and sent to an administrator that summarizes the maintenance problems and suggestions. This option may be pre-determined by the user. Time stamp and the associated parametric values may be logged and reported to the administrator for each automated response.

Cleaning and surface inspections may be scheduled in a number of different ways. In one embodiment a network administrator of the networked system may set a default maintenance frequency using a computer (802), a smart phone, or a wall-mount console 811. Such a setting may such as a command for cleaning, for example, dry clean panels two times per week and wet clean the panels once per month. Many other examples are possible. In one embodiment controller 807 may devise and implement its own flexible cleaning schedule on an “as needed” basis. Such a decision may be determined by real-time sensor data, image data, equipment status, and other performance metrics, as well as the weather forecast retrieved from the Internet.

In an embodiment utilizing intelligent digital servo drives, the system may be enabled to monitor the state and performance of each motor. Such information, in conjunction with encoder data and other sensor data may be used to predict problems that may arise in robot 812 or that might arise in other hardware before an actual failure event materializes. Such predictive maintenance capability could render routine scheduled robot maintenance obsolete.

FIG. 9 is a perspective view of a modular device array 900 according to an embodiment of the present invention. Modular device array 900 may be networked with other similar or dissimilar arrays. In this example the flat panels in array 900 are modular solar collecting devices. In one embodiment of the present invention, array 900 includes a robot system 901 including a gantry 902 that glides on two parallel but opposing tracks 905 situated at opposite ends of array 900. Gantry 902 serves as a platform supporting a cleaning module 903 analogous to module 812 described previously. Gantry 903 also supports an imaging module 904.

Cleaning module 903 is enabled to track back and forth over the width of array 900 along the direction of the double arrow along side gantry 902. Hoses and/or cables (not illustrated) may enter cleaning module 903 or robot 901 from one end of gantry 902 or they may be tucked underneath the gantry along its entire length. Gantry 902 may track back and forth over the entire length of array 900 supported on tracks 905.

In use the system divides work into manageable portions corresponding to the functional width of the modules. Cleaning module or robot 903 may continuously sweep over a strip of contiguous panels horizontally or vertically without stopping at the edge of each panel. At the edge of an array, the cleaning/imaging modules slide along Gantry 902 while the rest of the robot stays stationery before the sweeping motion resumes in the reverse direction. The bi-directional movement of the platform is coordinated with the side-to-side sliding movement of the modules until the compound motions sweep over the entire surface of an array. It is important to note herein that the mechanical reach of the robotic imaging and cleaning modules are such that full side-to-side travel and full front to rear travel is available to cover an entire modular device array.

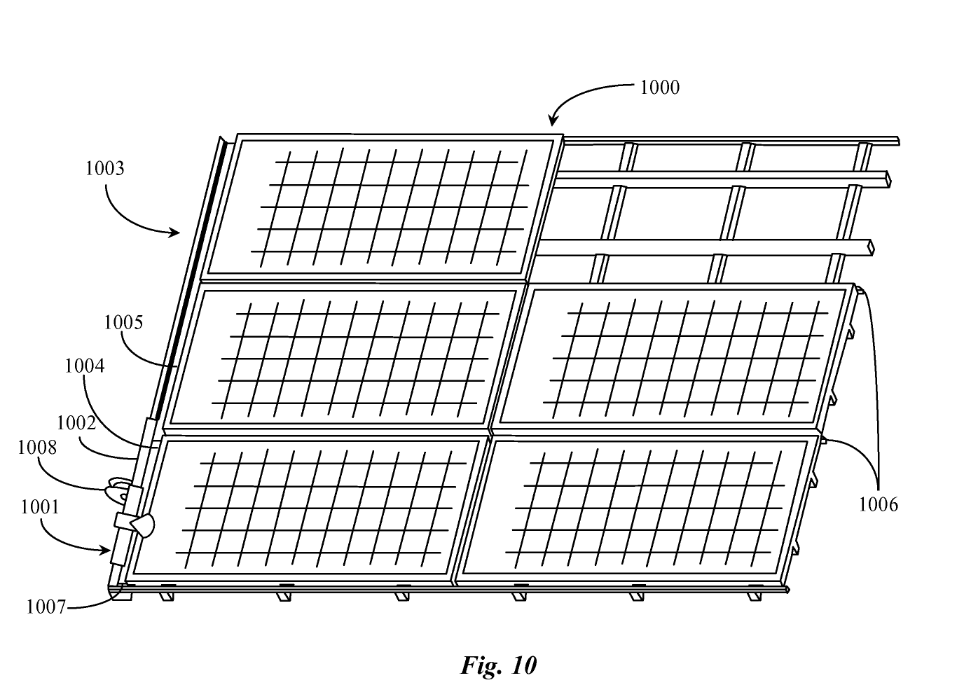

FIG. 10 is a perspective view of a modular device array 1000 including a lateral transfer system according to another embodiment of the present invention. Device array 1000 include multiple flat panels orientated in a lengthwise direction instead of along the width of the array as previously illustrated above with respect to FIG. 9. In this example, a robot 1001 includes a gantry 1002 that has the same or similar width as the flat panels, which are modular solar collecting devices in this case. This particular configuration may be useful in situations where the span of the array is very wide. A lateral transfer system (LTS) 1003 is provided at one end of array 1000. LTS 1003 consists of a lateral transfer vehicle (LTV) 1004, a guide channel 1005, and additional gantry tracks 1006 located under the gaps between panels.

LTS 1003 enables lateral robot movement along guide channel 1005 perpendicular to the direction of travel over panels to adjacent rows. The width of gantry 1002 may also be any multiple of the width of the flat panels. LTV 1004 may have built-in track extensions (1007) that are designed to line up with the main tracks to allow robot 1001 to roll on or to roll off of a next array track without a pause or a transitional step. LTV 1004 may be a self-propelled vehicle with an onboard motor. LTV 1004 may move along its own track on a side of guide channel 1005, or may be a passive vehicle pulled by a fixed motor mounted at the end of the guide channel. A reel 1008 may be provided and attached to LTV 1004 to ensure automatic alignment and release of supply hoses to the robot through a feeder/tensioner (not illustrated) mounted on robot 1001. In this example, the cleaning module and camera travels laterally back and forth over the width of the panels and lengthwise along the entire array.

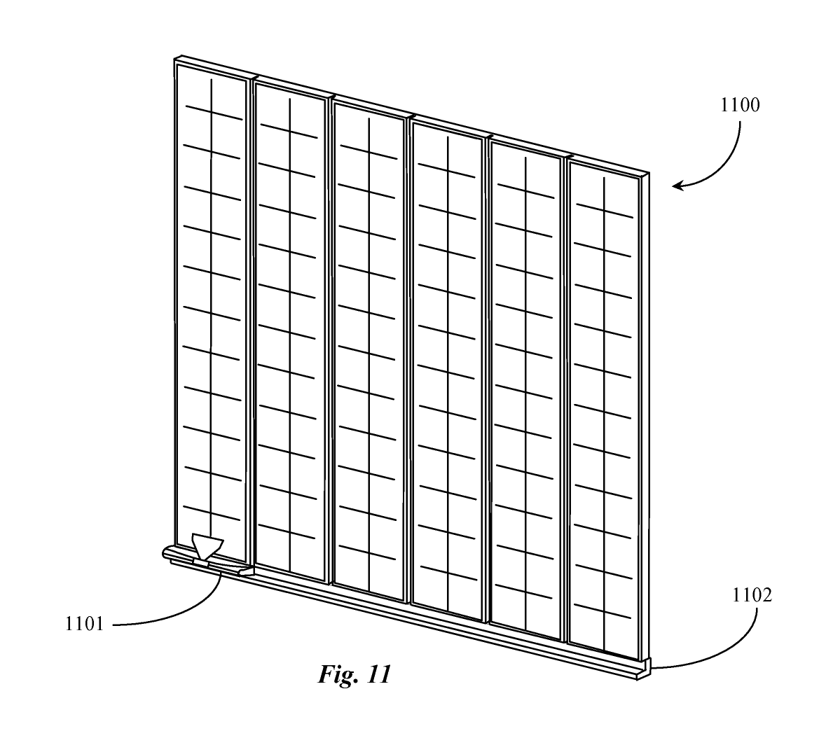

FIG. 11 is a perspective view of a flat panel array 1100 according to another embodiment of the present invention. Array 1100 has very narrow panels and includes a gantry robot 1101 that does not require any sliding modules. Array 1100 includes a lateral transfer system (LTS) 1102 located at one end of the array. LTS 1102 enables lateral robot transfer between rows and columns of the array depending on the orientation of the panels. This configuration may be suitable for arrays of long and narrow panels with gaps in between. The networked system may be configured in multitudes of different manners, depending at least in part on the size, shape and underlying support structure of the array.

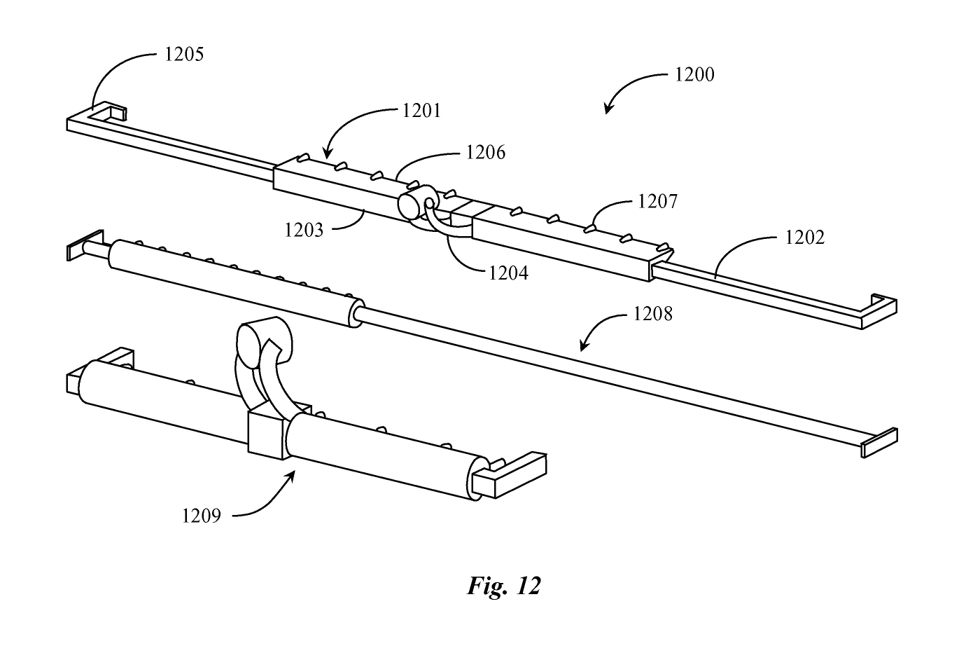

FIG. 12 is a perspective view of several gantry robot configurations according to an embodiment of the present invention. A gantry robot configuration 1200 includes a gantry robot 1201 with a cleaning module 1203 and an imaging module 1204. Other illustrated configurations include gantry robot configuration 1208 and gantry robot configuration 1209. All of these configurations are possible variations of gantry platform 902 described further above with respect to FIG. 9. Each platform has a payload that slides side-to-side along the gantry span. Common payloads may include a cleaning module 1203 and an imaging module 1204. Configuration 1208 does not include an imaging module.

Gantry robot 1200 includes flanges 1205 located at the ends of the gantry. These flanges may be utilized to mount motors and wheel assemblies (not illustrated). Although the robots may have sophisticated onboard sensors and data gathering capabilities, intelligence does not have to reside within the robots in the networked system, but in a remote controller elsewhere in the network.

One of the most critical goals for the networked system may be a long-term unmanned operational capability. To achieve such a goal, the cleaning module may or may not use supplies or consumables such as mopping pads, wiping pads, or cleaning solutions that have to be manually replaced or replenished at each array or robot end. At least two separate cleaning modes might be required to achieve efficient cleaning. For example, a dry cleaning mode and a wet cleaning mode may be provided. The cleaning module may also use a special cleaning solution with active enzymes to breakdown chemical bonds and dissolve “baked-in” bird droppings and the like.

In one embodiment of the invention an air knife 1206 is provided and adapted to lay down a laminar air flow for blowing off debris from an array. In another embodiment multiple spray nozzles 1207 are provided and adapted for wet cleaning by spraying a cleaning solution onto the target areas of an array. A combination of the two may provide non-contact cleaning using an uninterrupted supply of air and liquid from a central supply system. Air knife 1206 uses a high intensity, uniform sheet of laminar airflow to blow off liquid or debris. Cleaning module 1203 may deploy different tools for different cleaning situations. Air knife 1206 may be sufficient for dry cleaning. In one embodiment nozzles 1207 may first spray liquid solution on the target area. Then the liquid may be allowed to sit or soak for a period of time. Air knife 1206 may be used to blow off the remaining debris after the cleaning solution has broken it up.

In one embodiment, cleaning module 1203 may include a built-in steam generator that ejects stream through the nozzles to remove oil-based particulates and other sticky particulates. In an alternate embodiment the cleaning module may utilize a rotating cleaning head with wiping blades or brushes (not illustrated) in place of air knife 1206. After spraying and soaking, rotating heads may have to be lowered to make a physical contact with the panel surface. Blades or brushes may be made of rubber, plastics or other durable man-made materials.

In one embodiment of the present invention, an imaging module such as module 1204, for example, may play a critical role in panel inspection, performance monitoring and condition-based cleaning. For example, it may scan panel surfaces in infrared or other bands of electromagnetic spectrum to identify anomalies, check for cleanliness state and to characterize panels. Thermal images may be highly useful in identifying and diagnosing problems and may assist the system in solution recommendation. The scanned strips of images may be sent to controller for analysis and storage.

It will be apparent to the skilled artisan that the apparatus for cleaning and inspecting panel surfaces termed a robot cleaning module or payload may vary in length, shape, and capability without departing from the spirit and scope of the present invention. For example, cleaning module 1203 may be annular or rectangular. Gantry 1202 may be rectangular or annular. Many differing configurations are possible. The key aspect is the capability of the robotic component to inspect, report findings, and then to clean the flat panel surfaces accordingly.

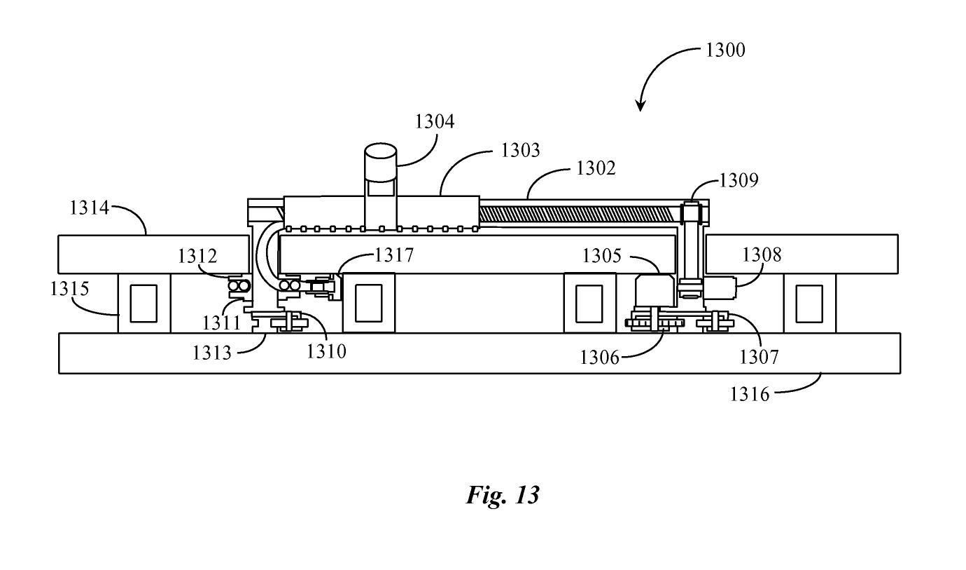

FIG. 13 is a cutaway view of a multi track robot 1300 according to an embodiment of the present invention. Multi-track robot 1300 includes a gantry platform 1302. Payloads provided in this example include a cleaning module 1303 with cleaning nozzles and or an air knife, and an imaging module 1304. The wheels of gantry platform 1302 run on tracks 1313 situated below panels 1314. In this embodiment the width of gantry platform 1302 matches the spacing between each row or column of supported flat panels 1316.

Flat panels 1314 are supported by support beams 1315 and by cross beams 1316 situated underneath the panels and comprising the framing structure for the array. In this embodiment robot 1300 is suitable for modular solar arrays. In one embodiment robot 1300 is driven along track 1313 by a main motor 1305 attached to a pinion gear 1306. Pinion gear 1306 together with guide wheels on the opposite side of the track and their housing, forms a driving wheel assembly 1307. An auxiliary motor 1308 is provided in this example and is adapted to power a linear drive mechanism 1309. Linear drive 1309 slides the gantry payloads along the span of the gantry. On the left leg of gantry 1300, a non-driving wheel assembly 1310 is provided and is adapted to guide the robot along the track.

The wheel assemblies are mounted perpendicularly to the gantry legs to fit in the limited space between the panels and the cross-beams. The entire drive mechanism is hidden under the panels. A feeder/tensioner 1311 is provided and adapted to assist robot pull hoses and/or cables 1312 from a reel underneath each array. A hose guide 1317 aids in changing the direction of the hoses.

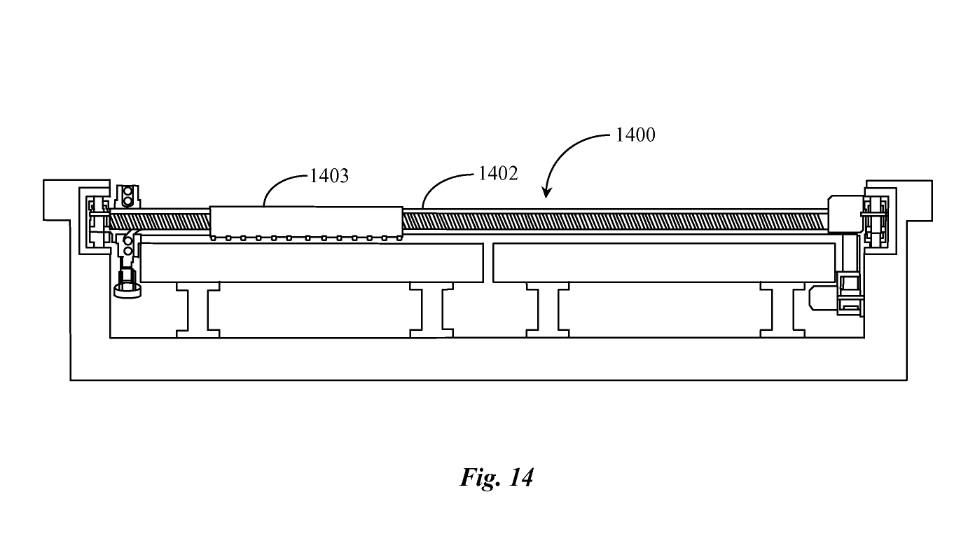

FIG. 14 is a cutaway view of a multi-track robot 1400 according to another embodiment of the present invention. Robot 1400 includes a cleaning module 1403 and a gantry platform 1402. In one embodiment gantry robot 1400 does not include gantry legs. Instead the wheels and motors thereof are mounted on flanges extending perpendicularly from the lengthy of the gantry. The wheels are positioned to run on the inside of the channels extending through the system at either end of each array. The cleaning module and a feeder tensioner for hose/cable assistance share the same axis. This present configuration is useful for a building having long vertical glass flat panels, for example.

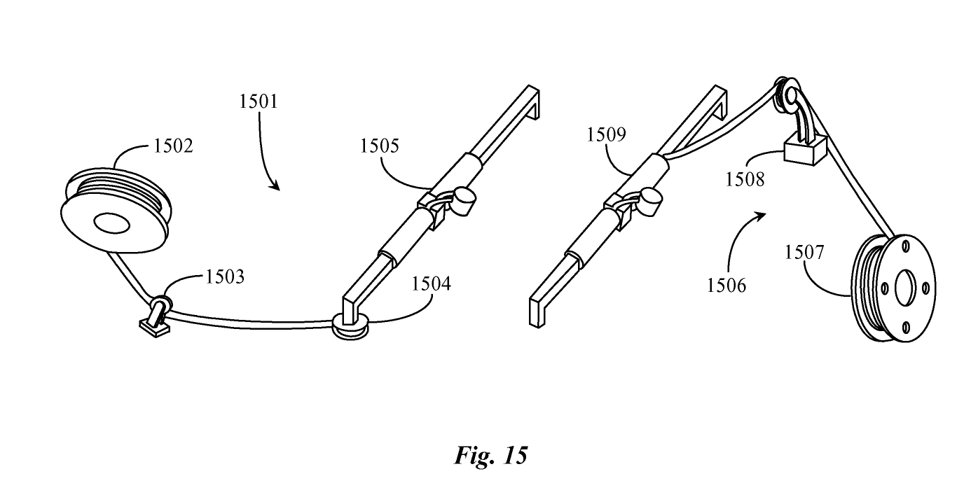

FIG. 15 is a perspective view of optional hose or cable feeder/tensioner assemblies for use in cleaning operations according to embodiments of the present invention. A feeder/tension assembly 1501 is provided and is illustrated as an optional assembly for supporting hose/cable management during a cleaning operation.

Assembly 1501 may be used for under-the-panel routing, where hoses or cables are routed from a reel 1502 attached to the system, through a hose guide 1503, and then through a feeder/tensioner 1504 installed on one of the gantry legs. The routed hoses enter the cleaning module 1505 on one of the gantry legs, before entering a cleaning module 1505.

A feeder/tension assembly 1506 is provided and is illustrated as an optional assembly for supporting hose/cable management during a cleaning operation. Assembly 1506 illustrated on the right hand side as viewed may be suited for over-the-panel routing.

Hose or cable travel from a reel 1507 to a swiveling feeder/tensioner 1508, then directed to a cleaning module 1509. Swiveling feeder/tensioner assembly 1508 may sit on its own track at the top of an array allowing a robot to simultaneously tow and draw hoses from it over the flat panels.

In a preferred use embodiment, as a robot scans and or cleans a flat panel surface of an array, a spring-loaded rotary hose feeder/tensioner with an auxiliary hose reel such as those illustrated and described in this example, draws hoses/cables from a main reel and maintains them in uniform tension while dampening stress and time lag as it overcomes inertia. A right amount of tension may prevent snag, tangle or kink of the hoses. A built-in tension sensor (not illustrated) may be provided trigger an emergency stop if the tension on hoses and/or cabling exceeds a preset limit. An external hose guide orientates hoses toward the feeder/tensioner at all times. It is noted herein that tracks may be of various shapes and sizes. Tracks may be manufactured of any one of a number of hard man-made or synthetic materials such as steel, aluminum, or plastics, depending in part on cost and durability. Tracks may be laid under, between, or on the sides of flat panels.

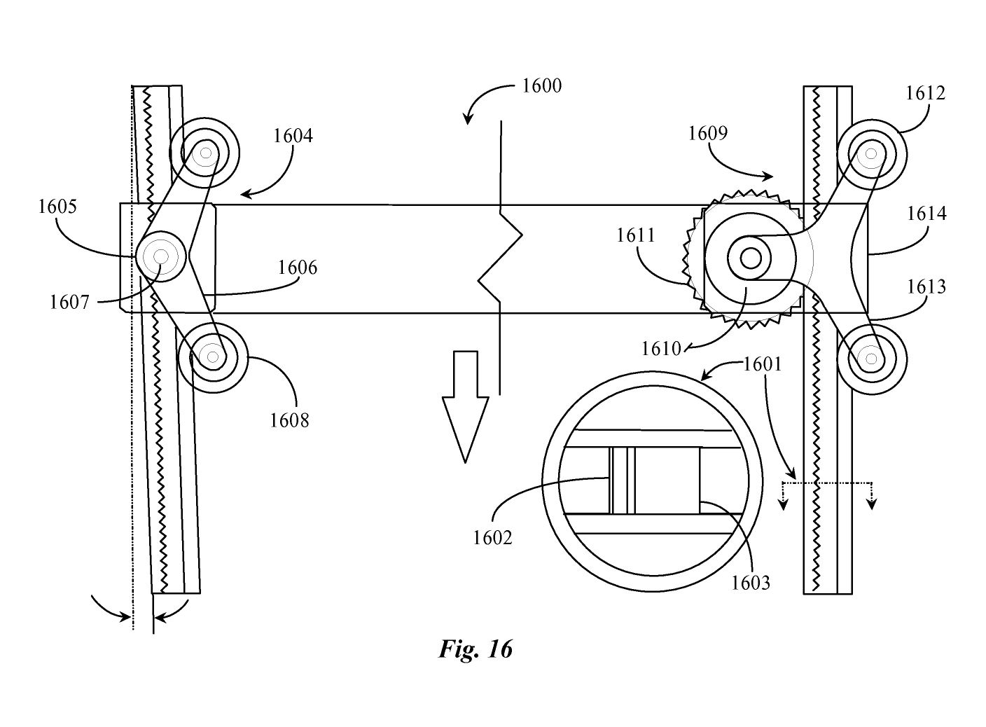

FIG. 16 is a top view of a robot tracking on a hybrid tracking system 1600 according to an embodiment of the present invention. Hybrid tracking system 1600 includes a deviation tolerant non-driving wheels assembly 1604 and a driving anti-torque wheel assembly 1609. Annular inset 1601 illustrates a double-sided hybrid track made of a gear rack sandwiched between two flat plates. This track embodiment includes a toothed rack side 1602 and a flat rail side 1603. The particular configuration allows for a pinion gear such as pinion gear 1611 on one side and wheels/rollers 1612 on the other. The hybrid tracks are mounted here on their sides directly on the cross-beams that run below panel support beams.

Because the robots ride on rigid tracks, it is important that the tracks are substantially parallel with spacing sufficient to prevent the robot's wheels from getting jammed between them. However, when the tracks are installed in the field, some deviations (θ) should be expected. One of the methods to compensate for the lack of precision and make the drive system more robust may be to make at least one of the two wheel assemblies “deviation-tolerant” such as assembly 1604 above.

On the non-driving side, the entire wheel assembly 1604 is mounted on the flange of the gantry 1605. The assembly includes two articulated links 1606. A coil spring (not illustrated) occupies the wheel housing along a common pivot axis 1607. The torsion of the spring pushes two wheels/rollers 1608 against the flat side of the track. When narrowing of the track occurs, the housing pivots and the angle between the links also narrow and vice versa. Such scissor-like action maintains constant traction on the wheels.

On the driving side, anti-torque driving wheel assembly 1609 includes a motor 1610. Motor 1610 is adapted to turn pinion gear 1611 against the rack side of the track. Twin wheels/rollers 1612 make intimate contact with the track from the rail side and counter-balance the momentum produced by motor 1610. A triple-pronged wheel housing 1613 is provided that bounds pinion gear 1611, motor 1610, and wheels 1612 together on a flange 1614 extending from one of the gantry legs. The robot tracks in the direction of

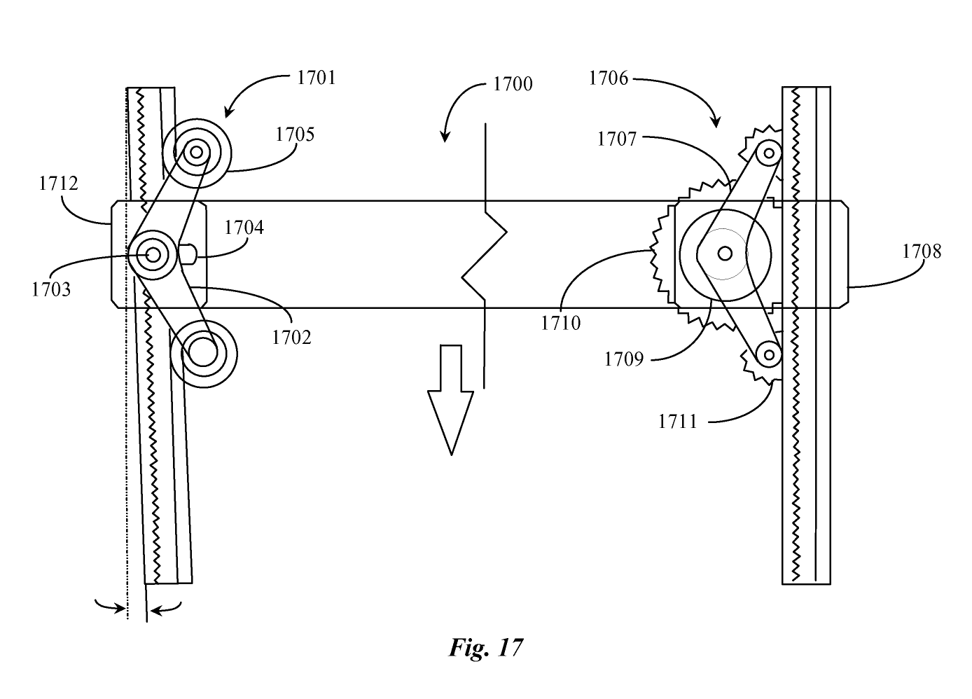

FIG. 17 is a top view of a robot tracking on a hybrid tracking system 1700 according to another embodiment of the present invention. In this example a left wheel assembly 1701 is provided as a non-driving wheel assembly. Wheel assembly 1701 includes a boomerang-shaped wheel housing 1702. Wheel housing 1702 has a pivot point at center 1703. Wheel housing 1702 pivots at center point 1703 and may move freely along slot 1704. Slot 1704 is cut into flange 1712 extending out from one of the gantry legs.

In use, a tension/compression spring (not illustrated) installed between wheel housing 1702 and the flange pushes the housing and its twin wheels/rollers 1705 outward against the flat side of the track, continuously adjusting to narrowing or widening of the track spacing in a deviant tolerant manner as described further above.

On a right wheel assembly 1706, a boomerang shaped wheel housing 1707 holds one large pinion gear 1710 and two small pinion gears 1711 together in mounted position on flange 1708 extending from the gantry. A motor 1709 mounted on flange 1708 turns large pinion gear 1710 to move the robot relative to the rack side of the track in the direction of the directional arrow.

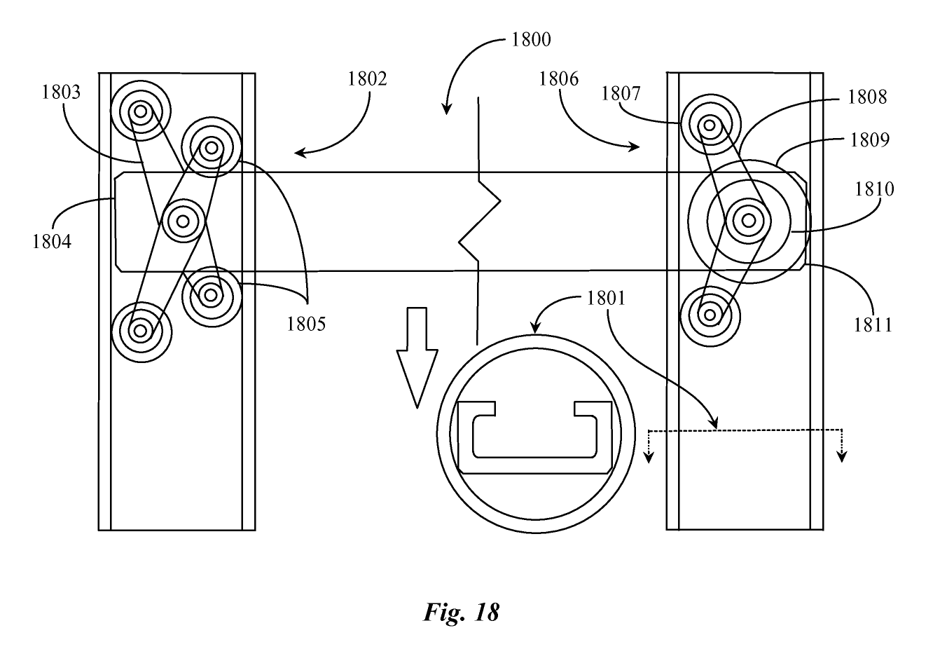

FIG. 18 is a top view of a robot tracking on a tracking system 1800 according to a further embodiment of the present invention. In this embodiment the hybrid tracks utilized in the previous examples are replaced by a C-shaped channel 1801 as shown in the annular inset taken from or expanded from section line 1801. A driving wheel assembly 1806 is provided and includes two small wheels 1807, and a large wheel 1809 held together in mounted position by a boomerang-shaped wheel housing 1808 and a flange 1811.

A non-driving wheel assembly 1802 is provided and includes a butterfly-shaped wheel housing 1803. Wheel housing 1803 has two links joined and pivoted at the center where it mounts to flange 1804. A torsion spring (not illustrated) installed between them pushes two of the wheels 1805 against the inside wall of the channel and the other two wheels 1805 against the opposite wall of the channel. The asymmetric shape of the links allows the wheel assembly to expand and fold to match the width of the channel while avoiding any contact between them.

Driving wheel assembly 1806 works in a manner similar to the non-driving wheel assembly except that it has three wheels instead of four wheels. The torsion spring on the common axis pushes twin wheels/rollers 1807 at the end of an articulated housing 1808 toward the inner wall of the C-shaped channel while the larger main wheel 1809 at the center pushes outward as well. This particular wheel assembly configuration may also be able to adjust itself to different channel widths, but in order to resist the moment produced by a motor 1810 mounted on flange 1811, the torsion spring may have to be fairly stiff. The motor urges the robot along the channel in the direction of the arrow. To remove either wheel assembly 1802 or 1806 from the respective channel, it has to be folded using a tool and a pin inserted through a hole (not illustrated) to lock the position before removal.

It will be apparent to a skilled artisan that the embodiments described above are exemplary of inventions that may have greater scope than any of the singular descriptions. There may be many alterations made in these examples without departing from the spirit and scope of the invention. For example, each robot may have an on-board controller. Robots of many different shape, sizes and configurations may be made of many different materials. Different versions of cleaning modules may have varying widths and effective coverage areas that may alter the number of passes and sweep sequence required to cover a whole panel or array. Certain embodiments of cleaning modules may utilize other contact and non-contact cleaning methods such as acoustic technologies. Imaging modules may adapt an alternate surface scanning technologies such as laser or electromagnetic bandwidths other than infrared. Sensor modules and other additional modules may be added on the payload list without departing from the spirit and scope of the invention. Different configurations of wheels may run on tracks of many shapes, sizes and materials. Air and liquid supplies and delivery systems may be installed at each array instead of at a central location. There are many possibilities.

### Retrograde Tracking for Solar Panels

In this specification a solar device refers to a discrete solar energy collection component. A solar device may be a solar photovoltaic (PV) cell, a chemical coated/treated substrate or heat-absorbing surface and may use crystalline silicon PV, thin film, concentrating solar, solar thermal or any other solar technology. The terms solar panel (a.k.a. solar module) is defined as a collection of one or more solar devices that are mounted together on a common base with built-in conduits for transferring energy to a larger energy storing/transmitting system or network. Solar array means a group or cluster of solar panels. Tracking panel, tracking array or more generic tracking unit refers to one or more of solar panels moving in unison on a common tilting plane.

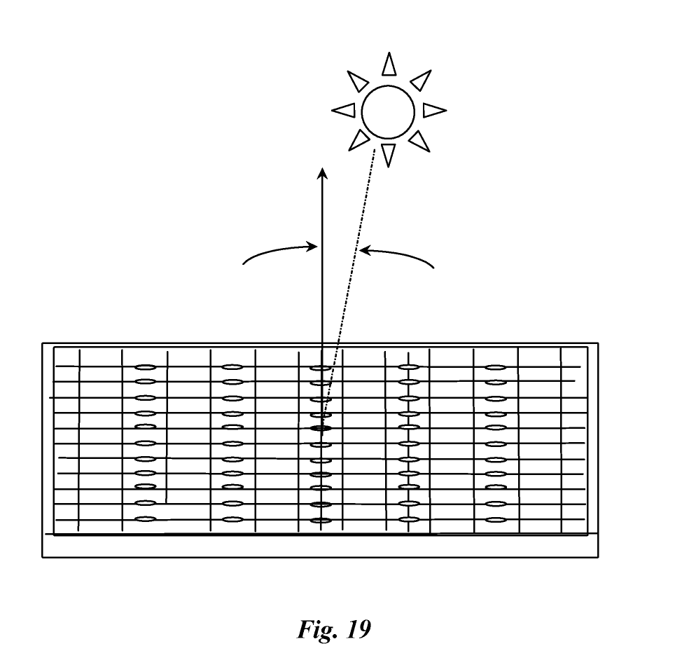

FIG. 19 is a logical block diagram illustrating angle of incidence (AOI) of the sun against a solar array. Regardless of the technology used, solar panels are most efficient when the angle of incident (AOI) is minimized as is illustrated herein. That is to say when the rays of the sun come in at an angle that is normal to the energy absorbing/converting surface then the angle is minimized. The general rule is that the larger the deviation from zero AOI, the smaller the amount of energy is available to the solar collection process. Therefore, it is a desire that solar tracking systems have minimal AOI as long as possible to maximize energy conversion efficiency.

Further to the above, commercial tracking systems may be either single axis or double axes systems. In a single axis system, panels face the sun and follow it as it rises from the east and sets in the west. This axis (FIG. 19) running north-south is often referred to as the primary axis. In addition to this daily east-west motion, a double-axes tracking system has a secondary axis that is used to adjust its tilt angle over a one year cycle to adapt to the seasonal variations of the sun resulting in higher elevation in the summer and lower in the winter.

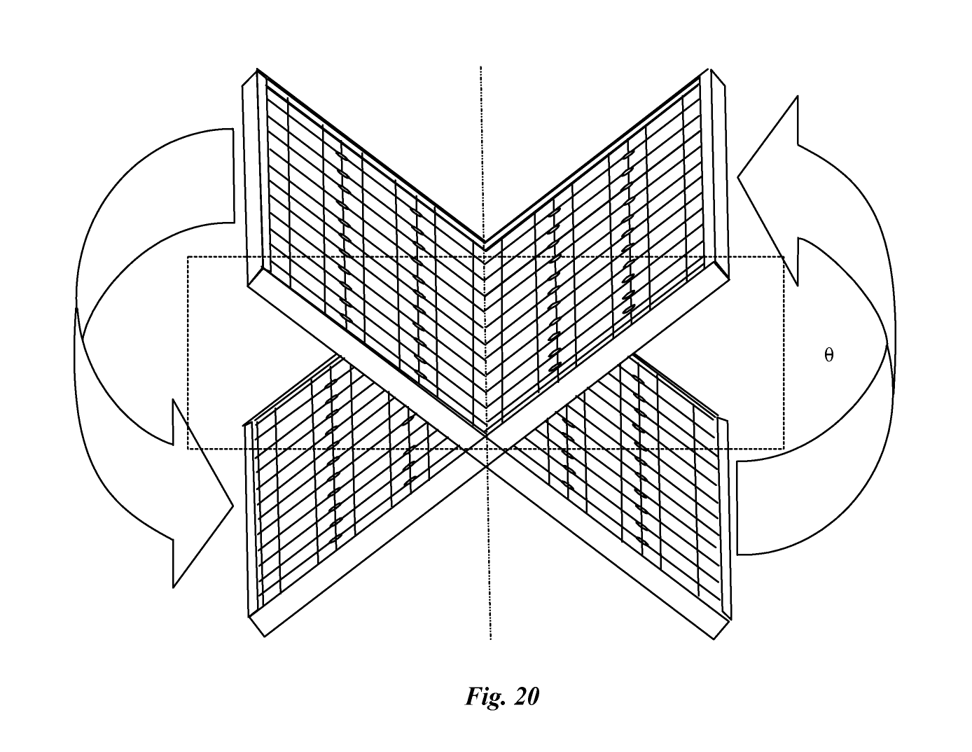

FIG. 20 is a block diagram illustrating an angular range of motion (AROM) for a solar panel according to an embodiment of the present invention. Tracking systems have angular range of motion (AROM). In this example, AROM equals to two times θ representing the tilt limit of the panel in either direction measured from the horizontal plane (broken rectangular boundary) in the east-west direction. Cross-shading, a term commonly used in solar jargon, refers to a condition that causes systemic shading of adjacent tracking units. It usually occurs at low sun angles due to insufficient inter-array spacing.

A typical tracking system known in the art uses synchronous motion (SM) where the panels always face the sun and tilt at the same constant rate in sync with the sun. In contrast to this standard method, the term counter-synchronous motion (CSM) coined by the inventor refers to a unique tilt motion activated in the opposite direction relative to the sun either toward or away from the sun. The angular trajectory is still, however, dependant on the position of the sun during tracking.

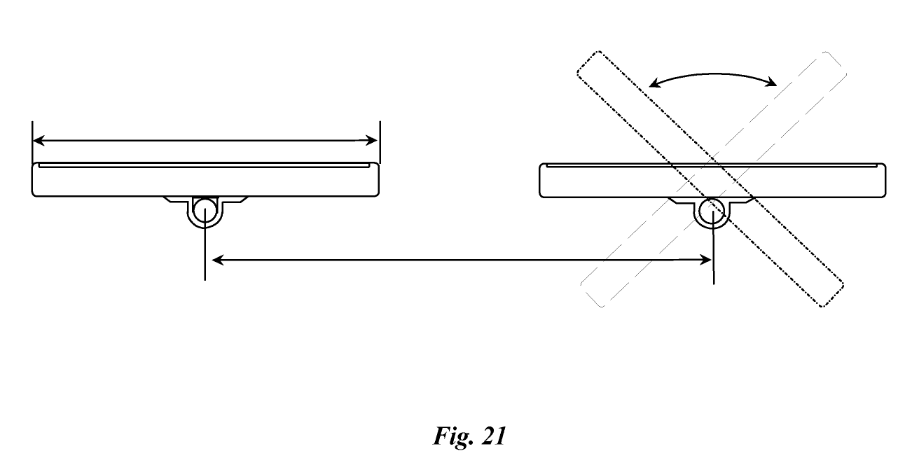

FIG. 21 is an elevation view of a modular device illustrating inter-array spacing or separation. The width of tracking unit is defined as the width seen along the direction of the primary axis. The distance between adjacent primary axes defines inter-array spacing or separation as shown in FIG. 21.

### Limitations of Conventional Tracking Systems

It is a well established fact that tracking solar arrays can produce substantially more energy (watts/panel) compared to fixed arrays of the same type and capacity. This difference is most pronounced for those using crystalline silicon PV technologies, where a single-axis tracking systems could add up to 30% more energy. However, there is a penalty involved. When one side of array is raised at low sun angles, the arrays cast larger shadows and require greater separation compared to their fixed counterparts. Again, this penalty is costliest for crystalline PV systems because relatively small shading may result in a disproportionate power reduction.

The overriding objective of a typical commercial rooftop installation is to achieve the highest energy density within a confined rooftop space. Obviously, the extra spacing lowers installation density in terms of the number of panels/unit of area. Because of the space, weight and other constraints, the fast-growing commercial segment has been largely bypassing the conventional tracking option.

Today, practically all rooftop-based commercial solar installations are fixed and most of the tracking systems can be found in large utility-scale ground-based installations in remote areas where space is relatively inexpensive and abundantly available. The tracking method described below addresses these shortcomings and may enable practical rooftop-based tracking solutions in the future.

### Retrograde Tracking

Unlike the conventional tracking systems that track the sun from horizon to horizon exclusively using synchronous motion (SM), retrograde tracking is a hybrid strategy incorporating a second element, a variable speed counter synchronous motion (CSM), in a seamless manner.

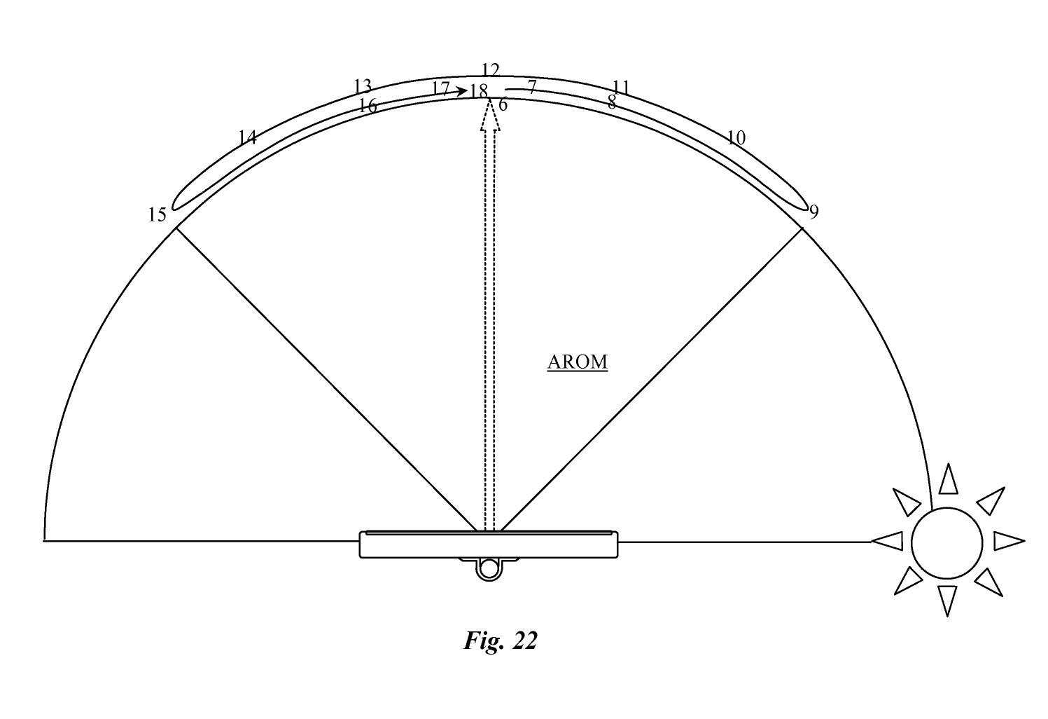

FIG. 22 is a chart illustrating retrograde tracking according to an embodiment of the present invention. In retrograde tracking, SM is used when the sun is within the system AROM (center region in FIG. 22) and CSM is used when the sun is outside of it (regions adjacent to center region in FIG. 22). Retrograde tracking requires a single-axis east-west retrograde motion, but a secondary axis may be combined to provide seasonal tilt adjustments in the north-south direction.

Successful implementation of retrograde tracking requires a proper inter-panel/array spacing that is a function of the panel/array width and their AROM. In an optimized embodiment, this is the minimum distance at which no cross-shading is possible when the sun is within the AROM. This arrangement creates an interference-free zone for SM (the center wedge).

Over the 12-hour span, the vector normal to the panel surface (dashed-line) sweeps the center AROM region twice (swings right, left, and then back to right) without crossing into the adjacent regions. That is to say both SM and CSM tracking take place within this center region. This pendulum-like motion is traced using a timeline at the top of the chart. The numbers on top of the chart represent hours in a 24-hour time period. The order of steps is as follows:
1) Panels are in the horizontal standby position as the sun rises from the east.
2) Panels gradually tilt east toward the sun until it reaches their tilt limit. (CSM tracking).
3) When the tilt limit is reached at the border, AOI is zero and panels reverse direction and start tilting in sync with the sun. (SM tracking)
4) When the tilt limit is reached again on the opposite side, the panels decouple from the sun and reverse direction once again to move away from the sun. (CSM tracking).
5) Panels eventually return to the horizontal standby position.

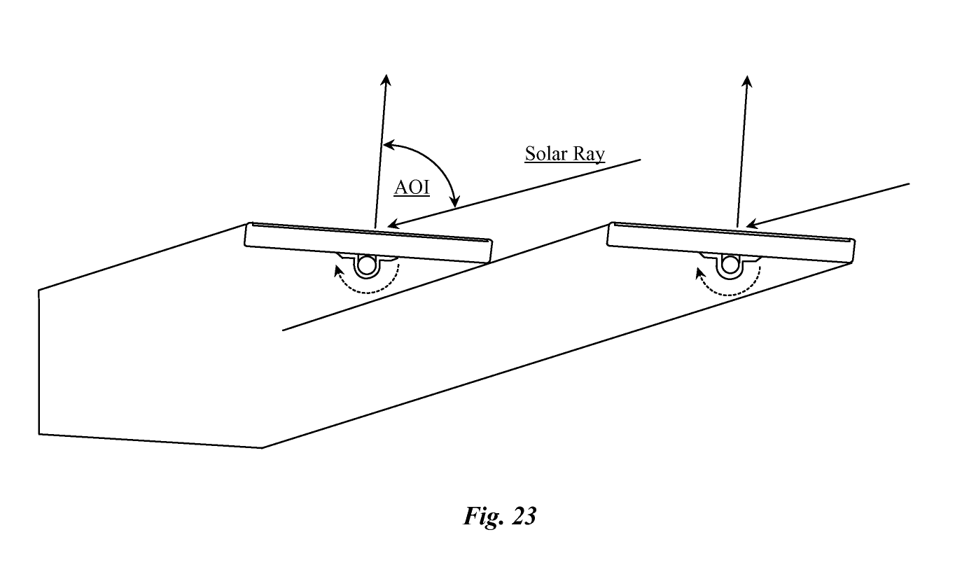

The following several examples illustrate SM and CSM tracking and the tracking functions illustrated in FIGS. 23 through 28 and Table 1 assume 90 degree AROM, sunrise at 6:00, sunset at 18:00 (equinox) and tracking conditions that allow 12 hours of continuous tracking. Panel angles in Table 1 below are measured relative to the horizontal plane in each example. At the start of tracking, the time is 6:00, the sun angle is 0, and the panel angle is 0. The panel remains in the horizontal position as the sun begins to rise.

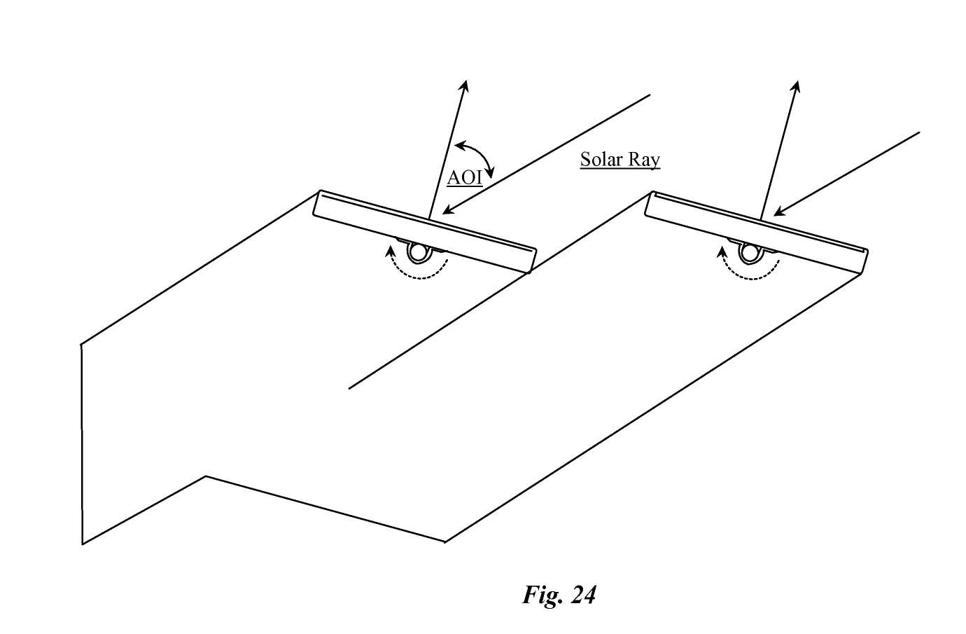

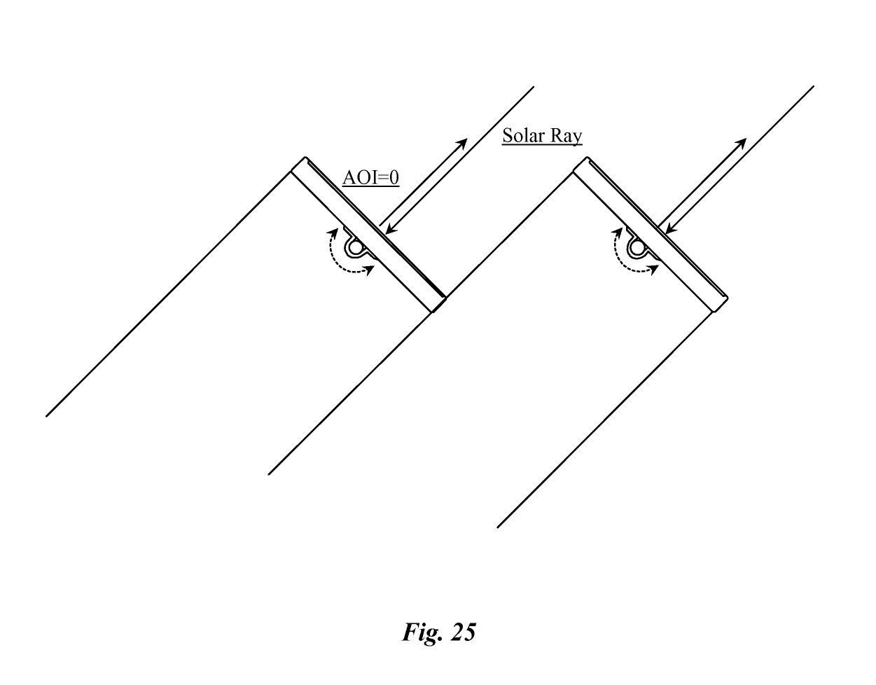

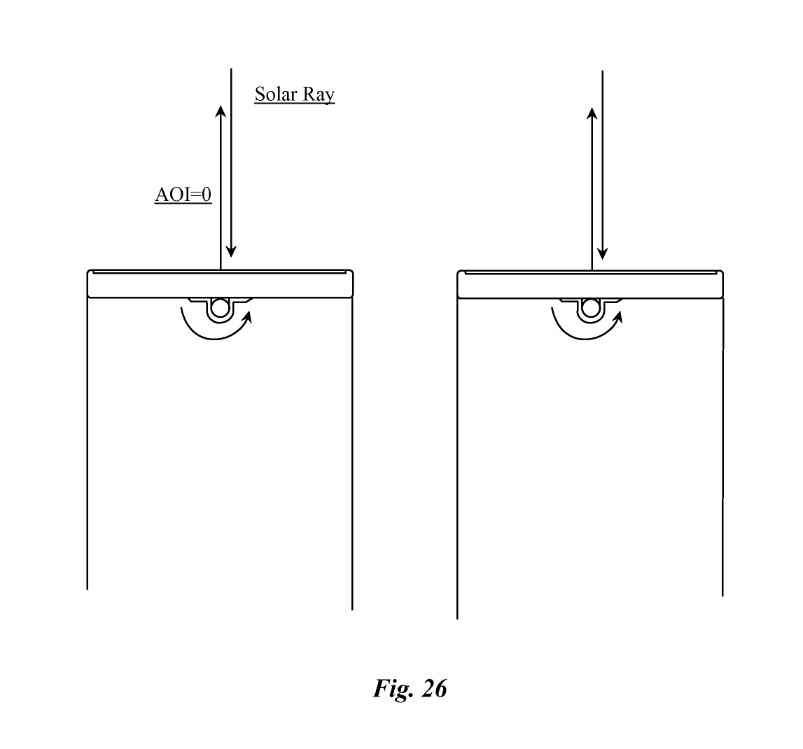

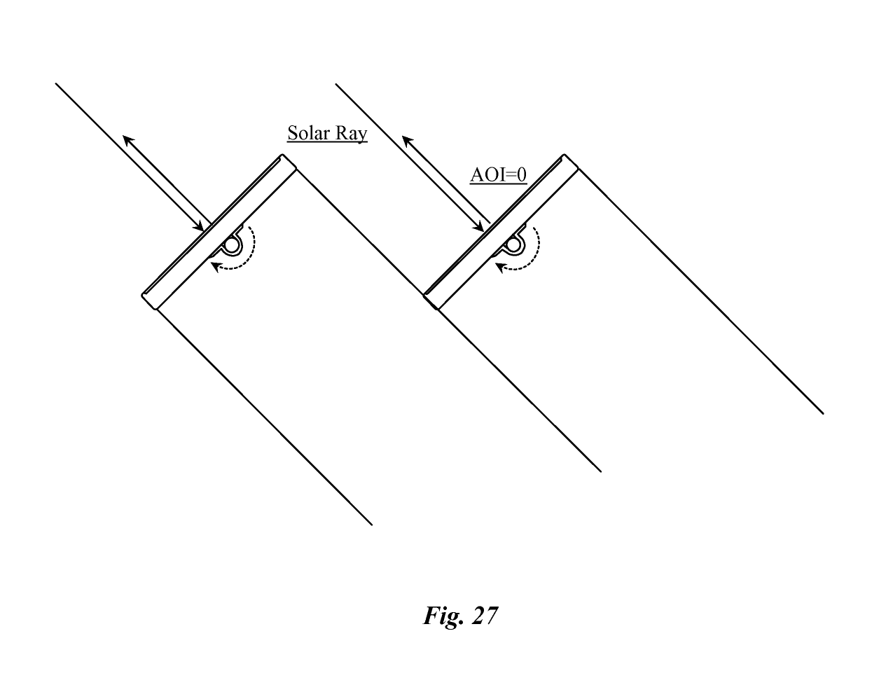

Referring now to FIG. 23, the time is 7:00, the sun angle on the panels is 15 degrees, the panel angle is 7 degrees, and the panels are turning slowly and simultaneously toward the sun (CSM tracking). Proper spacing prevents shadow cast onto the farthest panel from the sun. Referring now to FIG. 24, the time is 8:00, the sun angle on the panels is 30 degrees, the panel angle is 16 degrees, the tracking process picks up speed as the panels surfaces face the sun. Referring now to FIG. 25, the time is 9:00, the sun angle on the panels is 45 degrees, and the panel angle is also 45 degrees. The position is referred to as normal to the sun and the position minimizes the AOI. At this point the panels stop and begin to reverse direction (SM tracking). Referring now to FIG. 26, the time is 12:00, the sun angle on the panels is 90 degrees, and the angle of the panels is 0 representing the half way mark of the 12 hour tracking sequence. Referring now to FIG. 27, the time is 15:00, the sun angle on the panels is 135 degrees, and angle of the panels is −45 degrees.

At this point the CSM returns with another reversal in direction of movement. The remainder of table 1 describes the return movement back to an idle horizontal position sampled at time 16:00, 17:00, and finally at 18:00. The sampled angles of the sun on the panels is 150 degrees, 165 degrees, and 180 degrees respectively. The panel angles on the sampled points are −16 degrees, −7 degrees, and 0 degrees where the panels have returned to a horizontal position to wait for the next tracking sequence at 6:00 the following day.

| | SUN | PANEL | |
|---|---|---|---|
| TIME | ANGLE | ANGLE* | EVENTS |
| 6:00 | 0 | 0 | As the sun starts ascent, the panel |
| | | | is in the horizontal starting position. |
| 7:00 | 15 | 7 | Panels turning toward the sun |
| | | | (CSM) slowly to avoid shading. |
| | | | (FIG. 5) |
| 8:00 | 30 | 16 | Panels pick up speed at it nears |
| | | | the encounter with the sun (FIG. 6) |
| 9:00 | 45 | 45 | When panel surfaces become |
| 12:00 | 90 | 0 | normal to the sun at 9:00 (FIG. 7), |
| 15:00 | 135 | −45 | they reverse direction and SM |
| | | | begins. The half-way point is |
| | | | reached at 12:00 (FIG. 8). At |
| | | | 15:00 (FIG. 9), CSM returns with |
| | | | another reversal. |
| 16:00 | 150 | −16 | Panels are moving rapidly away |
| | | | from the sun to escape cross- |
| | | | shading. |
| 17:00 | 165 | −7 | The speed has slowed substantially |
| | | | as they near the “home” position. |
| 18:00 | 180 | 0 | Panels are back in the horizontal |
| | | | position and ready for the next day. |

Retrograde tracking using hybrid SM/CSM can be achieved with relatively small AROM and inter-panel/inter-array spacing compared to the conventional full-time SM tracking systems. These attributes are advantageous wherever the tracking units have to be placed in a relatively close proximity of each other, especially for, but not limited to rooftops. A method for tracking solar panels can be characterized by beginning a tracking cycle substantially at sunrise with adjacent tilting panels all horizontal; tilting the adjacent panels in unison in a first angular direction toward the rising sun at a tilt rate that just avoids shading of adjacent panels; reversing direction of panel tilt at a point that the panels reach either a maximum tilt limited by mechanical design, or the panel surfaces are orthogonal to the rising sun; tilting the adjacent panels in a second angular direction, following movement of the sun and keeping the surface of the panels at right angles to the sun's position, until a point is reached that shadowing is imminent from the angle of the setting sun and then reversing direction of panel tilt again to the first angular direction, adjusting tilt as the sun sets to avoid shading until the panels are again horizontal. Small spacing requirement is also conducive for small-scale light-weight systems that can track at the device, panel/module level, in addition to larger array/cluster level. The tracking system may minimize shading on adjacent panels in a pre-programmed way such that the amount of shading is pre-known and controlled by varying the tilt angle and speed of tilt. In one embodiment the shading varies according to the tilt angle.

One disadvantage of the retrograde tracking may be that the lower energy generation efficiency of CSM tracking relative to SM tracking. However, the actual difference between full-time SM tracking and retrograde tracking should be relatively minor due to the fact that CSM portion takes place during early-morning and late afternoon hours when the solar radiation is weak. The higher energy density of the retrograde tracking method may more than compensate for the slightly lower overall efficiency.

The ultimate choice of the tracking system may come down to the objective of individual installations. If it is to simply maximize energy production (total watts/installation) with no space constraint, a full-time SM tracking system should be employed. However, if the goal is to attain the highest energy producing capacity for a given installation space (watts/m2 or watts/ft2), retrograde tracking may be a better option. Development of a low-profile space-saving retrograde tracking hardware system may usher in a new era of rooftop-based tracking PV systems in the future.

### Modular Architecture

The inventor provides a unique low-profile modular architecture for rooftop and commercial solar panel arrays.

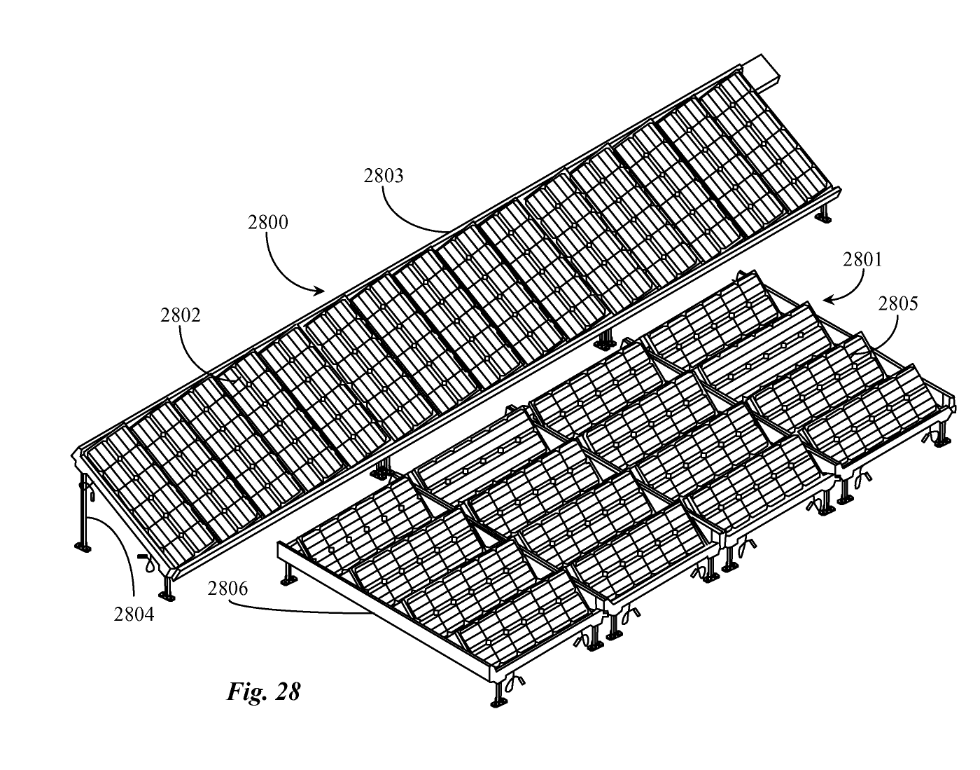

FIG. 28 is a perspective view illustrating two array configuration options according to an embodiment of the present invention. A solar panel array 2800 comprises adjacent modular solar collection devices 2802 installed in a linkable frame sub-system 2803. Devices 2802 are arrayed in a row and tilt along the length of the row in either direction. Array 2800 includes adjustable frame legs 2804 for adjusting the fixed angle of tilt to the slope of the roof. The individual solar devices or panels 2802 are linked to a tilting mechanism that provides SM and CSM tracking for all of the devices in unison.

A solar panel array 2801 comprises adjacent modular solar collection devices 2805 installed in a linkable frame sub-system 2806. Modular devices 2805 are arrayed in adjacent columns, each 4 panels or devices deep the devices in each column tilting along the height of the column in either direction.

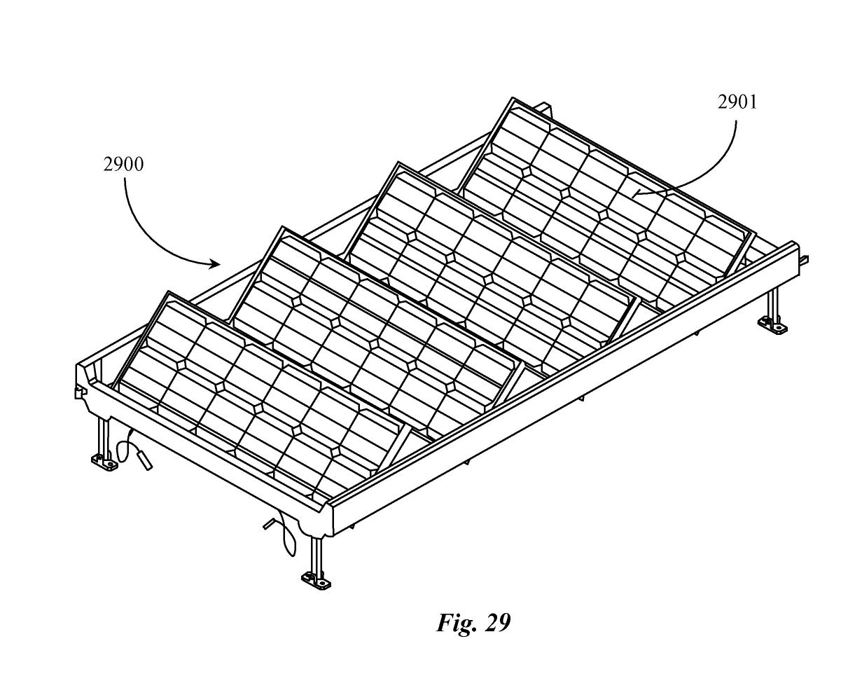

FIG. 29 is a perspective view of a single sub-frame section of linkable frame component 2806 of FIG. 28. All of the modular devices are linkable through tilt mechanism to enable tracking in unison with each modular device of a linked sub-frame tilting in unison in the same direction.

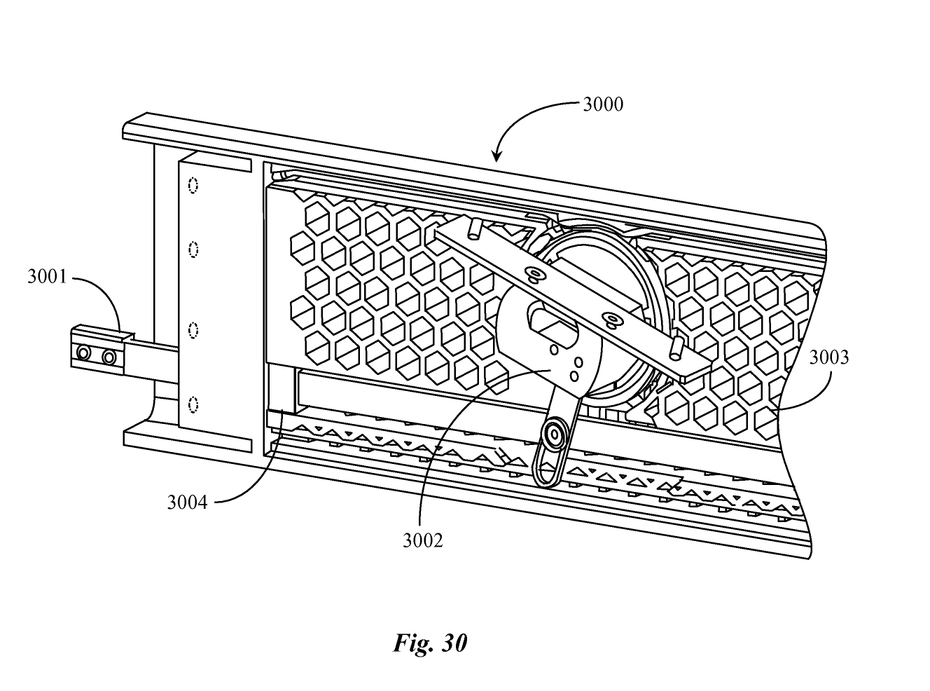

FIG. 30 is a partial view of a frame member 3000 according to an embodiment of the present invention. Frame member 3000 includes a plurality of tilt mechanisms 3002 installed on a tilt-bar (one shown). Each tilt mechanism supports a single modular solar collection device. A tilt bar linking clip 3001 is provided in this example to enable tilt-bar linking through multiple adjacent-system frames. In this way all of the modular devices in a device array can be linked to tilt in unison during SM and CSM tracking of the sun. A low-cost plain bearing is provided behind the linking clip to reduce tilt bar friction through the frame wall as it moves back and forth during tracking. The internal structure 3003 of frame member 3000 is honeycombed to increase strength while maintaining a light weight.

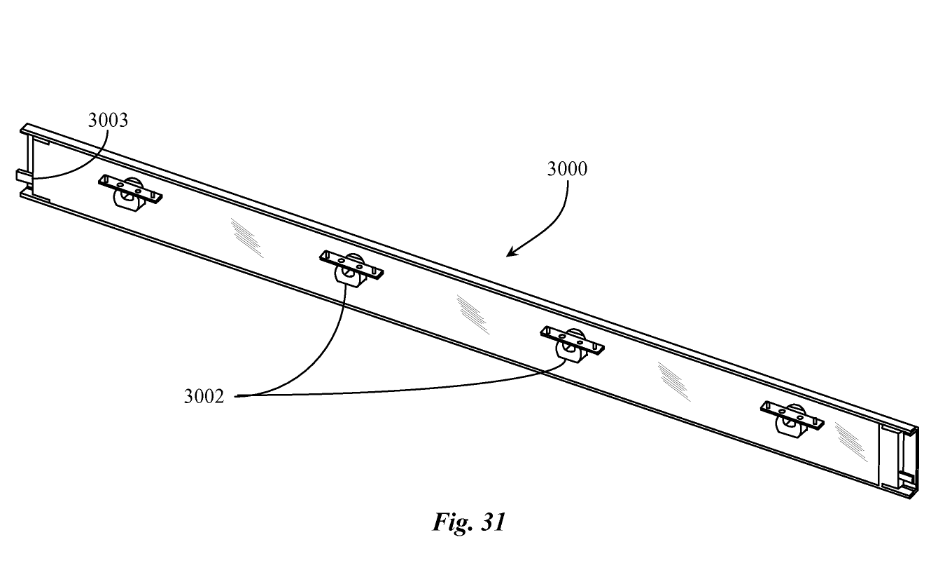

FIG. 31 is a perspective view of frame member 3000 of FIG. 30 showing outer skin and multiple tilt mechanisms. Frame member 3000 is a right side frame member. A left side frame member would support the other side of installed modular solar devices. Multiple tilt mechanisms 3002 are visible on the inside wall of the frame. The outer skin covers the internal honeycombed structure.

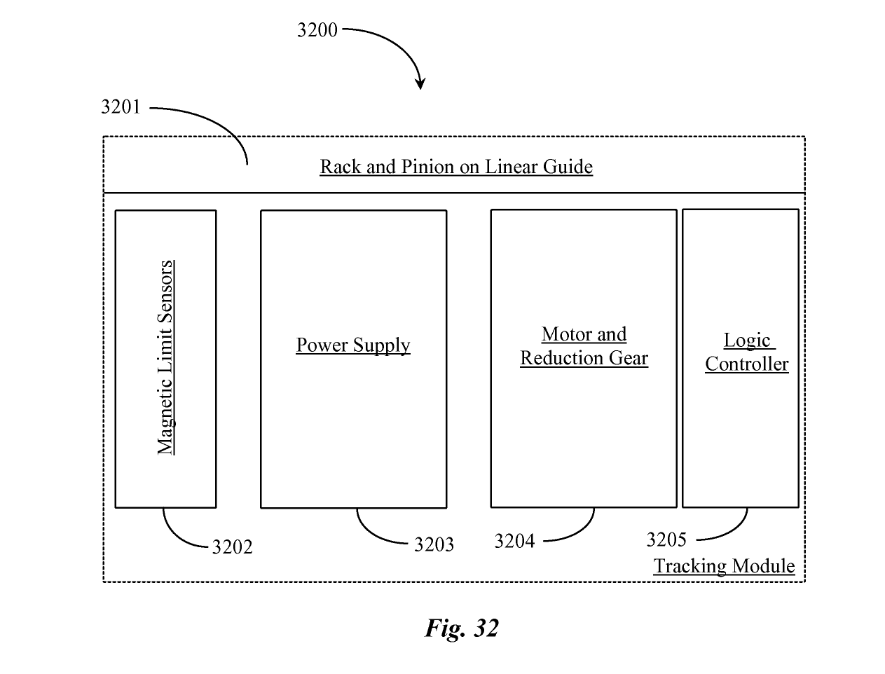

FIG. 32 is a block diagram illustrating basic tracking module components of a tracking module 3200. Tracking module 3200 is adapted to enable the system to perform both SM and CSM tracking as described previously. One tracking module may control tracking for multiple linked solar device arrays. Tracking module 3200 includes a rack and pinion 3201 installed on a linear guide. The rack slides on the linear guide and converts torque into precision linear motion.

Module 3200 includes one or more magnetic limit sensors 3200. Sensors 3200 enable calibration and validation of motor position in absence of an encoder. Tracking module 3200 includes a power supply 3203 that is adapted to store electricity collected from the PV modules in capacitors and for charging the battery. Tracking module 3200 includes a motor and reduction gear 3204 comprising a low cost and reliable stepper motor and a planetary gear head that is adapted to reduce speed and to boost torque. Tracking module 3200 includes a logic/controller 3205 which comprises the brain of the system and communication center for the system.

The tracking module may in one embodiment include USB ports for enabling diagnostic access to the device. The tracking module includes a battery service hatch for replacing rechargeable batteries, which may be a small swap of small lithium batteries (about once every 3 years.)

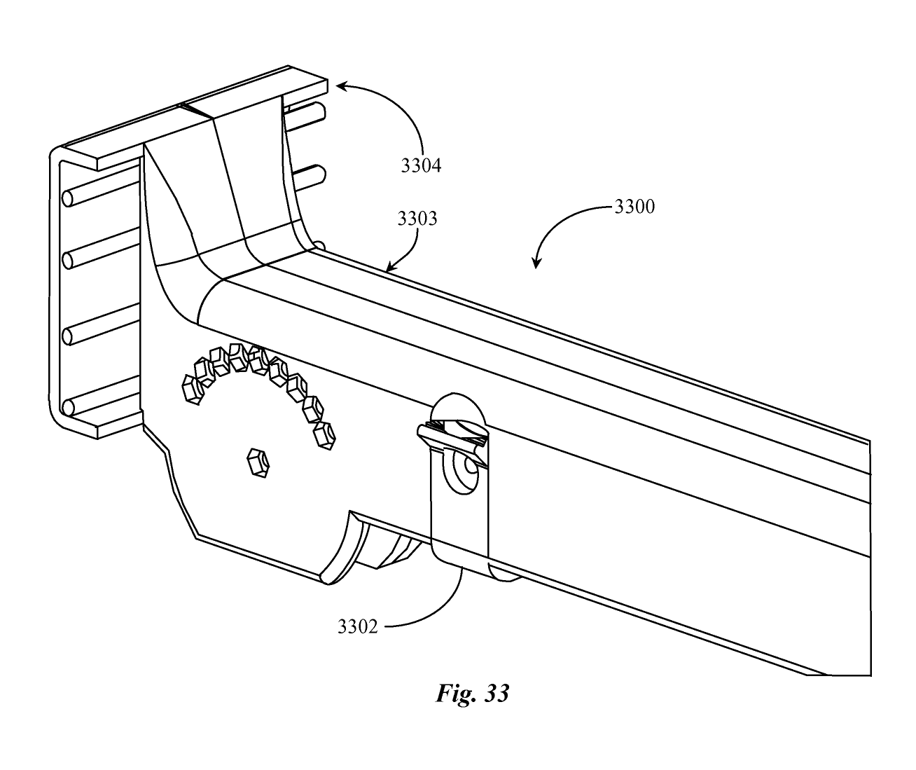

FIG. 33 is a partial view of a frame member 3300 of the modular solar collecting system of the present invention. Frame member 3300 has a low-set cross member. The frame sides that are parallel to PV panels are lowered and inside edges are rounded. This effectively increases the level of shade avoidance while tracking by the reduction in the minimum gap between the frame wall and first/last PV panel.

Frame member 3300 includes a push-on frame locking clip 3302 adapted to restrain movement between adjacent frames. In one embodiment, a bolt can be inserted through the clip for reinforcement. Frame member 3200 has overlapping joints 3304 including adjacent walls that fit inside channels and guides. The system also includes tight low-tolerance fit reinforced by studs. Outer coverings in the frame conceal a honeycombed internal structure that provides reinforcing strength but remains relatively light weight.

It will be apparent to one with skill in the art that the modular solar system of the invention may be provided using some or all of the mentioned features and components without departing from the spirit and scope of the present invention. It will also be apparent to the skilled artisan that the embodiments described above are specific examples of a single broader invention which may have greater scope than any of the singular descriptions taught. There may be many alterations made in the descriptions without departing from the spirit and scope of the present invention.

What is claimed is:

1. A method for tracking solar panels comprising the steps of:
(a) beginning a tracking cycle substantially at sunrise with adjacent tilting panels all horizontal;
(b) tilting the adjacent panels in unison in a first angular direction toward the rising sun at a tilt rate that just avoids shading of adjacent panels;
(c) reversing direction of panel tilt at a point that the panel surfaces are orthogonal to the rising sun;
(d) tilting the adjacent panels in a second angular direction, following movement of the sun and keeping the surface of the panels at right angles to the sun's position, until a point is reached just prior to the panels losing the orthogonal orientation with the sun when shadowing is imminent from the angle of the setting sun;
(e) reversing direction of panel tilt again to the first angular direction, adjusting tilt as the sun sets to avoid shading until the panels are again horizontal.

2. The method of claim 1 wherein, in steps (b) and (e) the tilting includes any one of a tilt rate that just avoids shading of adjacent panels and a tilt rate that allows a pre-programmed percentage of shading to occur.

3. The method of claim 2 wherein, in steps (b) and (e) the tilting allows a pre-programmed percentage of shading to occur, and the percentage varies with angle of tilt.

4. The method of claim 1 wherein tilting is accomplished in a continuous motion.

5. The method of claim 1 wherein tilting is accomplished incrementally at pre-programmed time increments.

6. A solar panel system comprising:
a plurality of solar panels having a length substantially greater than a width, mounted side-by-side with each panel enabled to tilt about along an axis in the direction of the length of the panel;
a tilting mechanism coupled to adjacent panels, capable of tilting the panels in either of two rotating directions about the panel axes; and
a programmable drive control enabled to control the rate and direction of tilt for the panels in unison in a tracking cycle;
wherein the tracking cycle begins substantially at sunrise with the panels horizontal, the panels are tilted in unison in a first angular direction toward the rising sun at a tilt rate that just avoids shading of adjacent panels, direction of tilt is reversed at a point that the panel surfaces are orthogonal to the rising sun, the panels are tilted in a second angular direction, following movement of the sun and keeping the surface of the panels at right angles to the sun's position, until a point is reached just prior to the panels losing the orthogonal orientation with the sun when shadowing is imminent from the angle of the setting sun, and tilting direction is reversed again to the first angular direction, adjusting tilt as the sun sets to avoid shading until the panels are again horizontal.

7. The system of claim 6 wherein the tilting includes any one of a tilt rate that just avoids shading of adjacent panels and a tilt rate that allows a pre-programmed percentage of shading to occur.

8. The system of claim 7 wherein the tilting allows a pre-programmed percentage of shading to occur and the percentage varies with angle of tilt.

9. The system of claim 6 wherein tilting is accomplished in a continuous motion.

10. The system of claim 6 wherein tilting is accomplished incrementally at pre-programmed time increments.
